(19) United States
(12) Patent Application Publication
(10) Pub. No.: US 2026/0219752 A1
(43) Pub. Date: Jul. 30, 2026

(54) ELECTRONIC DEVICE

(71) Applicant: Samsung Display Co., Ltd., Yongin-si (KR)

(72) Inventors: Hayeong NAM, Yongin-si (KR); JEONGYUN HAN, Yongin-si (KR); Jongmin LEE, Yongin-si (KR)

(21) Appl. No.: 19/409,958

(22) Filed: Dec. 5, 2025

(30) Foreign Application Priority Data
Jan. 24, 2025 (KR) 10-2025-0011687

(51) Int. Cl. G06F 3/041; G06F 3/044

(52) U.S. Cl. CPC G06F 3/0416; G06F 3/0446; G06F 3/0412; G06F 2203/04111; G06F 2203/04112; G06F 2203/04114

(57) ABSTRACT

An electronic device includes: a sensor layer including: first electrodes spaced from each other along a first direction; second electrodes spaced from each other along a second direction; third electrodes overlapping with the second electrodes; and fourth electrodes overlapping with the first electrodes. A sensing region includes sensing units including a first sensing unit spaced from a peripheral region, and a second sensing unit in contact with the peripheral region. The second electrodes include a (2-1)-th electrode overlapping with the first sensing unit, and a (2-2)-th electrode overlapping with the second sensing unit. The third electrodes include a (3-1)-th electrode overlapping with the (2-1)-th electrode, and a (3-2)-th electrode overlapping with the (2-2)-th electrode. A shape of a region overlapping with the (2-1)-th electrode and the (3-1)-th electrode and a shape of a region overlapping with the (2-2)-th electrode and the (3-2)-th electrode are different from each other.

### CROSS-REFERENCE TO RELATED APPLICATION

The present application claims priority to and the benefit of Korean Patent Application No. 10-2025-0011687, filed on Jan. 24, 2025, in the Korean Intellectual Property Office, the entire disclosure of which is incorporated by reference herein.

### BACKGROUND

Aspects of embodiments of the present disclosure relate to an electronic device having an improved sensing performance.

Multimedia electronic devices, such as a television, a mobile phone, a tablet computer, a laptop, a navigation system, and a game console, include a display device for displaying images. The electronic devices may include a sensor layer (e.g., an input sensor) to provide a touch-based input method that allows a user to intuitively and conveniently input information or commands, in addition to other suitable input methods, such as a button, a keyboard, and/or a mouse. The sensor layer may sense a user's touch or pressure. From among users who are accustomed to entering information using a writing instrument, demands for using a pen for a more precise touch input or for certain applications (e.g., applications for sketching or drawing) have been increasing.

### SUMMARY

Embodiments of the present disclosure may be directed to an electronic device having an improved sensing performance.

According to one or more embodiments of the present disclosure, an electronic device includes: a sensor layer having a sensing region, and a peripheral region adjacent to the sensing region; and a sensor driver configured to drive the sensor layer. The sensor layer includes: a plurality of first electrodes spaced from each other along a first direction; a plurality of second electrodes spaced from each other along a second direction crossing the first direction; a plurality of third electrodes overlapping with the plurality of second electrodes; and a plurality of fourth electrodes overlapping with the plurality of first electrodes. The sensing region includes a plurality of sensing units along the first direction and the second direction, and the plurality of sensing units include a first sensing unit spaced from the peripheral region, and a second sensing unit in contact with the peripheral region. The plurality of second electrodes includes a (2-1)-th electrode overlapping with the first sensing unit, and a (2-2)-th electrode overlapping with the second sensing unit. The plurality of third electrodes include a (3-1)-th electrode overlapping with the (2-1)-th electrode, and a (3-2)-th electrode overlapping with the (2-2)-th electrode. A shape of a region overlapping with the (2-1)-th electrode and the (3-1)-th electrode and a shape of a region overlapping with the (2-2)-th electrode and the (3-2)-th electrode are different from each other.

In an embodiment, the (2-1)-th electrode may include x first split electrodes apart from each other along the second direction, where x may be an integer; and the (2-2)-th electrode may include y second split electrodes spaced from each other along the second direction, where y may be an integer.

In an embodiment, the x may be larger than the y.

In an embodiment, the x and the y may be same as each other; and a pitch between the first split electrodes may be larger than a pitch between the second split electrodes.

In an embodiment, the (3-1)-th electrode may include x third split electrodes overlapping with the first split electrodes in a one-to-one correspondence, where x may be an integer; and the (3-2)-th electrode may include y fourth split electrodes overlapping with the second split electrodes in a one-to-one correspondence, where y may be an integer.

In an embodiment, an area of each of the first split electrodes and an area of each of the second split electrodes may be same as each other; and an area of each of the third split electrodes may be smaller than an area of each of the fourth split electrodes.

In an embodiment, an area of each of the first split electrodes may be smaller than an area of each of the second split electrodes; and an area of each of the third split electrodes and an area of each of the fourth split electrodes may be same as each other.

In an embodiment, a width of the first sensing unit in the second direction may be larger than a width of the second sensing unit in the second direction.

In an embodiment, a first opening may be in the (2-1)-th electrode; and a second opening having a size smaller than a size of the first opening may be in the (2-2)-th electrode.

In an embodiment, a width of the (3-1)-th electrode in the second direction may be smaller than a width of the (3-2)-th electrode in the second direction.

In an embodiment, the (2-1)-th electrode may have a mesh structure having a first line width; the (2-2)-th electrode may have a mesh structure having a second line width; the (3-1)-th electrode may have a mesh structure having a third line width; and the (3-2)-th electrode may have a mesh structure having a fourth line width.

In an embodiment, the first line width and the second line width may be same as each other; and the fourth line width may be larger than the third line width.

In an embodiment, the third line width and the fourth line width may be same as each other; and the second line width may be larger than the first line width.

In an embodiment, the second line width may be larger than the first line width; and the fourth line width may be larger than the third line width.

In an embodiment, the sensor driver may be configured to selectively operate in a first mode for sensing a touch input and in a second mode for sensing a pen input. The second mode may include a charging driving mode and a pen sensing driving mode, and in the charging driving mode, the sensor driver may be configured to provide a first signal to at least any one third electrode among the plurality of third electrodes, and a second signal to at least another third electrode among the plurality of third electrodes. In the pen sensing driving mode, the sensor driver may be configured to receive first reception signals from the plurality of first electrodes and second reception signals from the plurality of second electrodes.

According to one or more embodiments of the present disclosure, an electronic device includes: a display layer configured to display an image; a sensor layer on the display layer, and having a sensing region and a peripheral region adjacent to the sensing region; and a processor configured to control operations of the display layer and the sensor layer. The sensor layer includes: a plurality of first electrodes spaced from each other along a first direction; a plurality of second electrodes spaced from each other along a second direction crossing the first direction; a plurality of third electrodes overlapping with the plurality of second electrodes; and a plurality of fourth electrodes overlapping with the plurality of first electrodes. The plurality of second electrodes include a (2-1)-th electrode, and a (2-2)-th electrode spaced from the (2-1)-th electrode in the second direction. The plurality of third electrodes include a (3-1)-th electrode overlapping with the (2-1)-th electrode, and a (3-2)-th electrode overlapping with the (2-2)-th electrode. The (3-1)-th electrode includes a plurality of first split electrodes overlapping with the (2-1)-th electrode, and the (3-2)-th electrode includes a plurality of second split electrodes overlapping with the (2-2)-th electrode. An area of a region, in which each of the plurality of first split electrodes overlaps with the (2-1)-th electrode, is smaller than or equal to an area of a region, in which each of the plurality of second split electrodes overlaps with the (2-2)-th electrode.

In an embodiment, a number of the plurality of first split electrodes may be greater than a number of the plurality of second split electrodes.

In an embodiment, the (2-1)-th electrode may have a mesh structure having a first line width; the (2-2)-th electrode may have a mesh structure having a second line width; the (3-1)-th electrode may have a mesh structure having a third line width; and the (3-2)-th electrode may have a mesh structure having a fourth line width. The first line width and the second line width may be same as each other, and the fourth line width may be greater than the third line width; or the third line width and the fourth line width may be same as each other, and the second line width may be greater than the first line width; or the second line width may be greater than the first line width, and the fourth line width may be greater than the third line width.

In an embodiment, a first opening may be in the (2-1)-th electrode; and a second opening having a size smaller than a size of the first opening may be in the (2-2)-th electrode.

In an embodiment, a width of each of the plurality of first split electrodes in the second direction may be smaller than a width of each of the plurality of second split electrodes in the second direction.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a block diagram of an electronic device according to an embodiment of the present disclosure;

FIG. 2A is a perspective view of an electronic device according to an embodiment of the present disclosure;

FIG. 2B is a rear perspective view of an electronic device according to an embodiment of the present disclosure;

FIG. 3 is a perspective view of an electronic device according to an embodiment of the present disclosure;

FIG. 4 is a perspective view of an electronic device according to an embodiment of the present disclosure;

FIG. 5 is a schematic cross-sectional view of a display panel according to an embodiment of the present disclosure;

FIG. 6 is a drawing illustrating an operation of an electronic device according to an embodiment of the present disclosure;

FIG. 7A is a cross-sectional view of a display panel according to an embodiment of the present disclosure;

FIG. 7B is a cross-sectional view illustrating a partial configuration of a sensor layer according to an embodiment of the present disclosure;

FIG. 8 is a plan view of a sensor layer according to an embodiment of the present disclosure;

FIG. 9A is a plan view illustrating a first conductive layer of a sensing unit according to an embodiment of the present disclosure;

FIG. 9B is a plan view illustrating a second conductive layer of a sensing unit according to an embodiment of the present disclosure;

FIG. 10 is an enlarged plan view of the region AA′ illustrated in FIG. 9B;

FIG. 11 is a plan view illustrating a sensing unit according to an embodiment of the present disclosure;

FIG. 12A is a plan view illustrating two sensing units according to an embodiment of the present disclosure;

FIG. 12B is a plan view illustrating two sensing units according to an embodiment of the present disclosure;

FIG. 13A is an enlarged plan view of the region BB′ illustrated in FIG. 12A;

FIG. 13B is an enlarged plan view of the region BB′ illustrated in FIG. 12A;

FIG. 13C is an enlarged plan view of the region BB′ illustrated in FIG. 12A;

FIG. 13D is an enlarged plan view of the region BB′ illustrated in FIG. 12A;

FIG. 14A is an enlarged plan view of the region BB′ illustrated in FIG. 12A;

FIG. 14B is an enlarged plan view of the region BB′ illustrated in FIG. 12A;

FIG. 15A is a cross-sectional view of a sensor layer according to an embodiment of the present disclosure;

FIG. 15B is a cross-sectional view of a sensor layer according to an embodiment of the present disclosure;

FIG. 15C is a cross-sectional view of a sensor layer according to an embodiment of the present disclosure;

FIG. 16 is a plan view illustrating two sensing units according to an embodiment of the present disclosure;

FIG. 17 is a diagram illustrating an operation of a sensor driver according to an embodiment of the present disclosure;

FIG. 18 is a diagram illustrating an operation of the sensor driver according to an embodiment of the present disclosure;

FIG. 19 illustrates a first mode according to an embodiment of the present disclosure;

FIG. 20 illustrates a second mode according to an embodiment of the present disclosure;

FIG. 21A is a graph illustrating a waveform of a first signal according to an embodiment of the present disclosure;

FIG. 21B is a graph illustrating a waveform of a second signal according to an embodiment of the present disclosure;

FIG. 22A illustrates a second mode according to an embodiment of the present disclosure; and

FIG. 22B illustrates a second mode based on one sensing unit according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein (e.g., the various modules, units, and/or the like) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

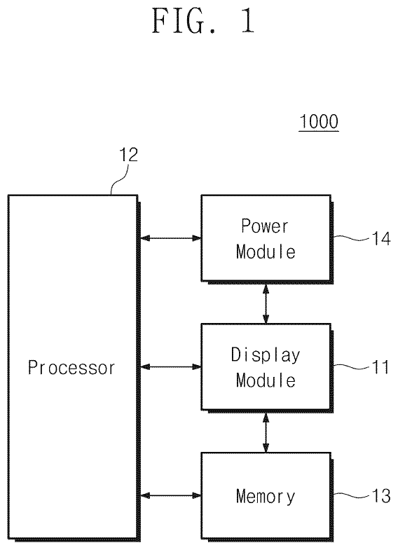

FIG. 1 is a block diagram of an electronic device 1000 according to an embodiment of the present disclosure.

Referring to FIG. 1, the electronic device 1000 according to an embodiment of the present disclosure may include a display module (e.g., a display or a touch-display) 11, a processor 12, a memory 13, and a power module (e.g., a power supply) 14.

The display module 11 may display an image. The image may include a dynamic image as well as a still image. The processor 12 may include at least one of a central processing unit CPU, an application processor AP, a graphic processing unit GPU, a communication processor CP, an image signal processor ISP, or a controller. The processor 12 may control the operations of the display module 11.

The memory 13 may store data information used for the operations of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power used for the operations of the electronic device 1000.

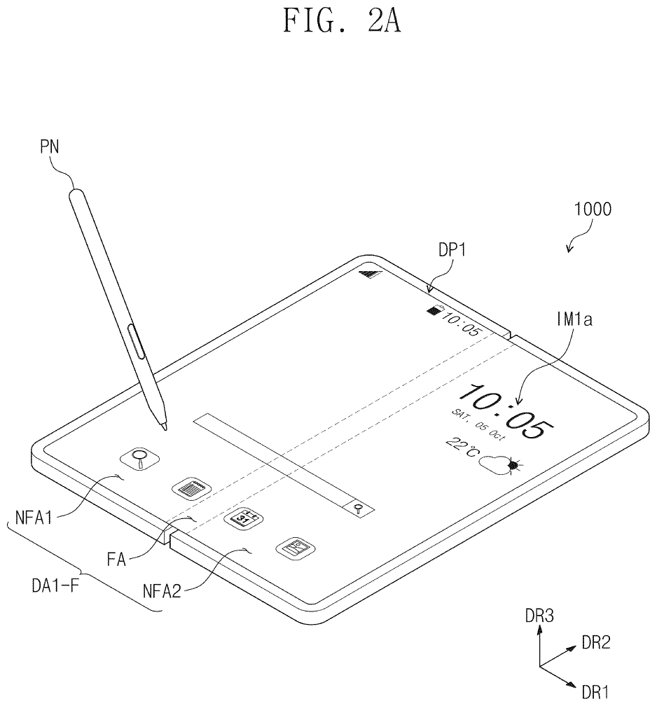

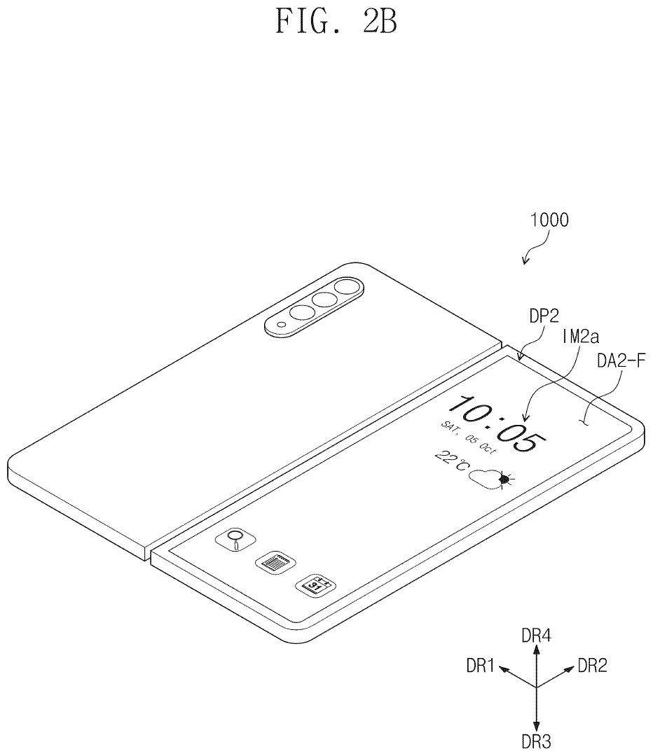

FIG. 2A is a perspective view of an electronic device 1000 according to an embodiment of the present disclosure. FIG. 2B is a rear perspective view of the electronic device 1000 according to an embodiment of the present disclosure.

Referring to FIGS. 2A and 2B, the electronic device 1000 may be activated according to an electrical signal. For example, the electronic device 1000 may display an image and sense inputs applied from the outside. The external input may be a user's input. The user's input may include various suitable forms of external inputs, such as a part of the user's body, a pen PN, light, heat, or pressure.

The electronic device 1000 may include a first display panel DP1 and a second display panel DP2. The first display panel DP1 and the second display panel DP2 may be separate panels from each other. The first display panel DP1 may be referred to as a main display panel, and the second display panel DP2 may be referred to as an auxiliary display panel or an external display panel.

The first display panel DP1 may include a first display portion DA1-F, and the second display panel DP2 may include a second display portion DA2-F. The area of the second display panel DP2 may be smaller than the area of the first display panel DP1. Depending on the sizes of the first display panel DP1 and the second display panel DP2, the area of the first display portion DA1-F may be larger than the area of the second display portion DA2-F.

When the electronic device 1000 is unfolded, the first display portion DA1-F may have a plane parallel to or substantially parallel to a first direction DR1 and a second direction DR2. The thickness direction of the electronic device 1000 may be parallel to or substantially parallel to a third direction DR3 crossing the first direction DR1 and the second direction DR2. Accordingly, the front surfaces (e.g., the upper surfaces) and rear surfaces (e.g., the lower surfaces) of members constituting the electronic device 1000 may be defined based on the third direction DR3.

The first display panel DP1 or the first display portion DA1-F may include a folding region FA that may be folded and unfolded, and a plurality of non-folding regions NFA1 and NFA2 spaced apart from each other with the folding region FA interposed between the non-folding regions NFA1 and NFA2. The second display panel DP2 may overlap with any one of the plurality of non-folding regions NFA1 and/or NFA2. For example, the second display panel DP2 may overlap with a first non-folding region NFA1.

The display direction of a first image IM1a displayed on the first display panel DP1 and the display direction of a second image IM2a displayed on the second display panel DP2 may be opposite to each other. For example, the first image IM1a may be displayed in the third direction DR3, and the second image IM2a may be displayed in a fourth direction DR4 that is opposite to the third direction DR3.

In an embodiment of the present disclosure, the folding region FA may be bent based on a folding axis extending along a direction parallel to or substantially parallel to a long side of the electronic device 1000, for example, such as a direction parallel to or substantially parallel to the second direction DR2. When the electronic device 1000 is folded, the folding region FA has a suitable curvature (e.g., a predetermined curvature) and a suitable curvature radius (e.g., a predetermined curvature radius). The first non-folding region NFA1 and the second non-folding region NFA2 may face each other, and the electronic device 1000 may be inner-folded so that the first display portion DA1-F is not exposed to the outside.

In an embodiment of the present disclosure, the electronic device 1000 may be outer-folded so that the first display portion DA1-F is exposed to the outside. In an embodiment of the present disclosure, the electronic device 1000 may be both inner-folded and outer-folded from an unfolded state, but the present disclosure is not limited thereto.

FIG. 2A illustrates that one folding region FA is defined (e.g., provided or included) in the electronic device 1000, but the present disclosure is not limited thereto. For example, a plurality of folding axes and a plurality of folding regions corresponding thereto may be defined in the electronic device 1000, and from an unfolded state, the electronic device 1000 may be inner-folded and/or outer-folded in each of the plurality of folding regions.

According to an embodiment of the present disclosure, at least one of the first display panel DP1 or the second display panel DP2 may sense an input by a pen PN even though it does not include a digitizer. Accordingly, because the digitizer for sensing the pen PN may be omitted, an increase in the thickness and the weight of the electronic device 1000, as well as a decrease in its flexibility due to the addition of a digitizer, may not occur. Therefore, not only the first display panel DP1, but also the second display panel DP2, may be designed to sense the pen PN.

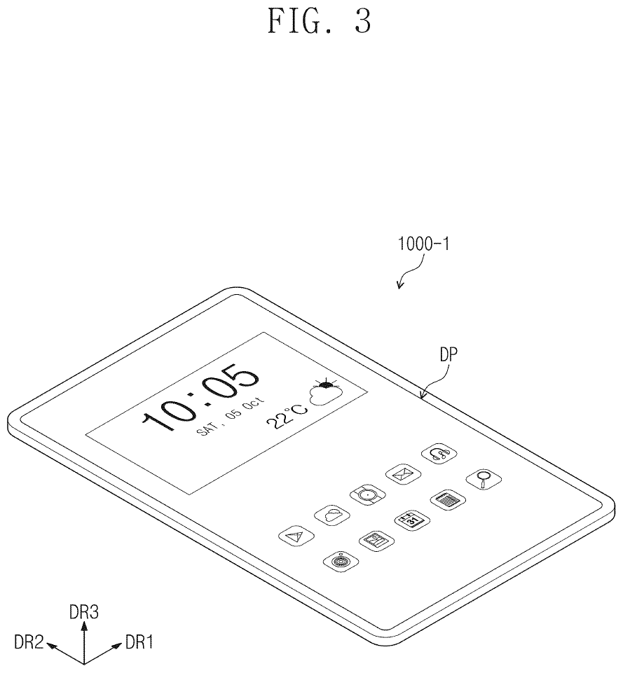

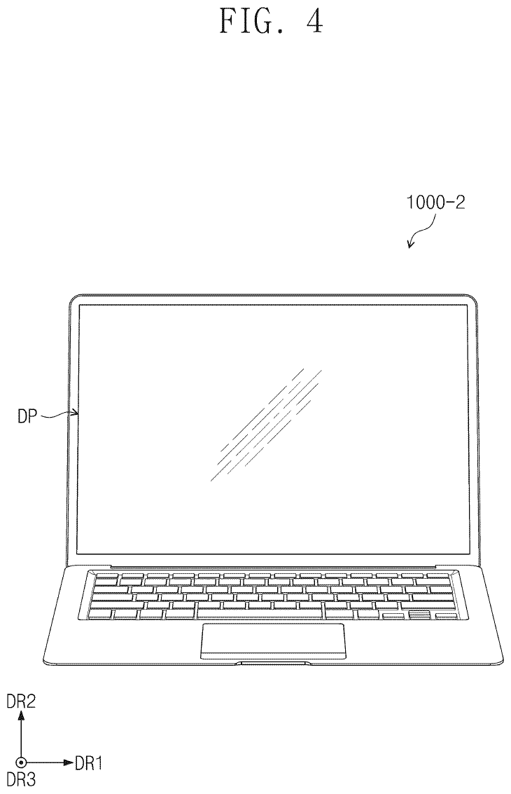

FIG. 3 is a perspective view of an electronic device 1000-1 according to an embodiment of the present disclosure. FIG. 4 is a perspective view of an electronic device 1000-2 according to an embodiment of the present disclosure.

FIG. 3 illustrates that the electronic device 1000-1 is a bar-kind of mobile phone, and the electronic device 1000-1 may include a display panel DP. FIG. 4 illustrates that the electronic device 1000-2 is a laptop, and the electronic device 1000-2 may include a display panel DP. FIG. 4 is a perspective view of the electronic device 1000-2, but the coordinate axes included in FIG. 4 are indicated based on the display panel DP in the electronic device 1000-2.

In an embodiment of the present disclosure, the display panel DP may sense inputs (e.g., external inputs) applied from the outside. An external input may be a user's input. The user's input may include various suitable forms of external inputs, such as a part of the user's body, a pen PN (e.g., see FIG. 2A), light, heat, or pressure.

According to an embodiment of the present disclosure, the display panel DP may sense an input by the pen PN even though it does not include a digitizer. Therefore, because the digitizer for sensing the pen PN may be omitted, an increase in the thickness and the weight of the electronic device 1000-1 or 1000-2 due to the addition of a digitizer may not occur.

FIG. 2A illustrates a foldable-kind of electronic device 1000, and FIG. 3 illustrates a bar-kind of electronic device 1000-1, but the present disclosure is not limited thereto. For example, the embodiments described in more detail below may be applied to various suitable kinds of electronic devices, such as a rollable-kind of electronic device, a slidable-kind of electronic device, and a stretchable-kind of electronic device.

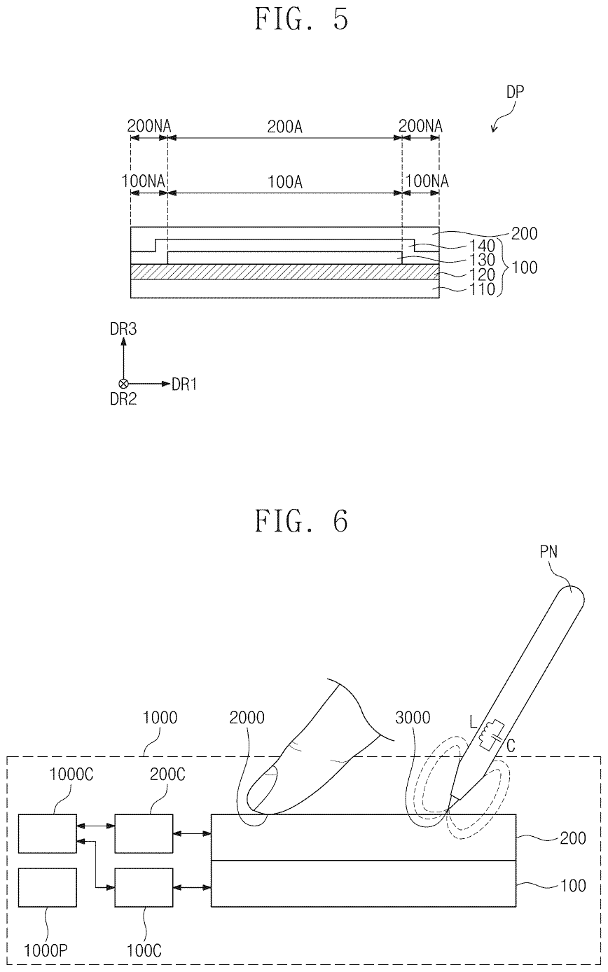

FIG. 5 is a schematic cross-sectional view of a display panel DP according to an embodiment of the present disclosure.

Referring to FIG. 5, the display panel DP may include a display layer 100 and a sensor layer 200. An upper functional member may be further disposed on the sensor layer 200. For example, the upper functional member may include at least one of an anti-reflection layer, a window, or a protective film.

The display layer 100 may be a component that generates or substantially generates an image. A display region 100A and a non-display region 100NA adjacent to the display region 100A may be defined in the display layer 100. An image may be displayed in the display region 100A.

The display layer 100 may be a light-emitting display layer, and for example, the display layer 100 may be an organic light-emitting display layer, an inorganic light-emitting display layer, an organic-inorganic light-emitting display layer, a quantum dot display layer, a micro LED display layer, or a nano LED display layer. The display layer 100 may include a base layer 110, a circuit layer 120, a light-emitting element layer 130, and an encapsulation layer 140.

The base layer 110 may be a member that provides a base surface on which the circuit layer 120 is disposed. The base layer 110 may have a multi-layered structure or a single-layer structure. The base layer 110 may be a glass substrate, a metal substrate, a silicon substrate, a polymer substrate, or the like, but the present disclosure is not particularly limited thereto.

The circuit layer 120 may be disposed on the base layer 110. The circuit layer 120 may include an insulating layer, a semiconductor pattern, a conductive pattern, a signal line, and the like. An insulating layer, a semiconductor layer, and a conductive layer may be formed on the base layer 110 by coating, deposition, or the like, and the insulating layer, the semiconductor layer, and the conductive layer may be selectively patterned through a plurality of photolithography processes.

The light-emitting element layer 130 may be disposed on the circuit layer 120. The light-emitting element layer 130 may include a light-emitting element. For example, the light-emitting element layer 130 may include an organic light-emitting material, an inorganic light-emitting material, an organic-inorganic light-emitting material, a quantum dot, a quantum rod, a micro LED, or a nano LED.

The encapsulation layer 140 may be disposed on the light-emitting element layer 130. The encapsulation layer 140 may protect the light-emitting element layer 130 from moisture, oxygen, and foreign substances, such as dust particles.

The sensor layer 200 may be disposed on the display layer 100. A sensing region 200A and a peripheral region 200NA adjacent to the sensing region 200A may be defined in the sensor layer 200. The sensing region 200A may overlap with the display region 100A, and the peripheral region 200NA may overlap with the non-display region 100NA.

According to an embodiment of the present disclosure, the area of the sensing region 200A may be greater than or equal to the area of the display region 100A. FIG. 5 illustrates that the area of the sensing region 200A and the area of the display region 100A are the same or substantially the same as each other, but the present disclosure is not limited thereto. For example, a portion of the sensing region 200A may overlap with the non-display region 100NA, and the area of the sensing region 200A may be larger than the area of the display region 100A. In this case, although an input occurs adjacent to the boundary between the display region 100A and the non-display region 100NA, a signal may be sufficiently recognized because the sensing region 200A overlaps with a portion of the non-display region 100NA. Therefore, a coordinate accuracy for a touch input at the outer boundary of the display region 100A may be further improved.

The sensor layer 200 may sense an external input applied from the outside. The sensor layer 200 may be an integrated sensor that is continuously formed during the manufacturing process of the display layer 100, or the sensor layer 200 may be an external sensor that is attached to the display layer 100. The sensor layer 200 may be referred to as a sensor, an input sensing layer, an input sensing panel, or an electronic apparatus for sensing input coordinates.

According to an embodiment of the present disclosure, the sensor layer 200 may sense both inputs from a passive-kind of input means, such as a user's body, and inputs from an input device that generates a magnetic field at a suitable resonant frequency (e.g., a predetermined resonant frequency). The input device may be referred to as a pen, an input pen, a magnetic pen, a stylus pen, or an electromagnetic resonance pen.

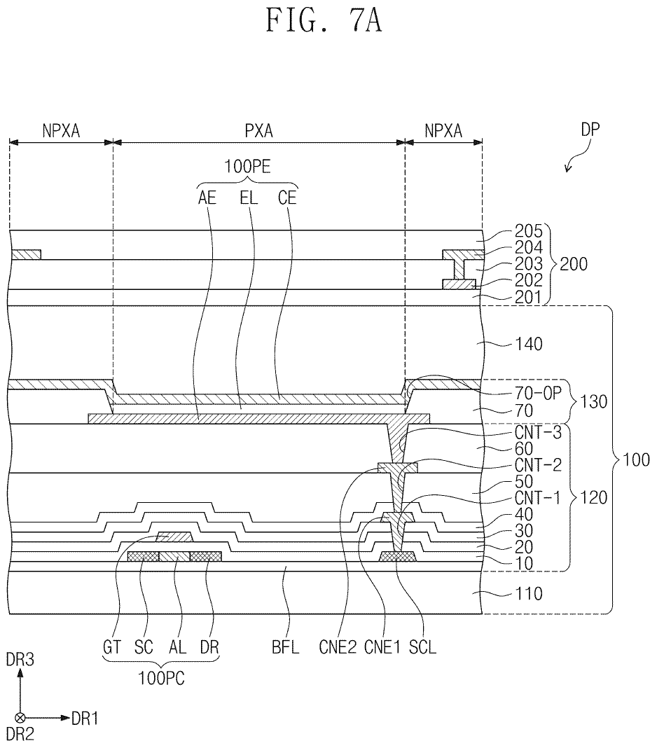

FIG. 6 is a drawing illustrating an operation of the electronic device 1000 according to an embodiment of the present disclosure.

Referring to FIG. 6, the electronic device 1000 may include a display layer 100, a sensor layer 200, a display driver 100C, a sensor driver 200C, a main driver 1000C, and a power circuit 1000P.

The sensor layer 200 may sense a first input 2000 or a second input 3000 applied from the outside. Each of the first input 2000 and the second input 3000 may be an input by an input means capable of providing a change in a capacitance of the sensor layer 200, or an input by an input means capable of causing an induced current in the sensor layer 200. For example, the first input 2000 may be an input by a passive-kind of input means, such as a user's body. The second input 3000 may be an input by a pen PN, or an input by an RFIC tag. For example, the pen PN may be a passive-kind of pen or an active-kind of pen.

In an embodiment of the present disclosure, the pen PN may be a device that generates a magnetic field at a suitable resonant frequency (e.g., a predetermined resonant frequency). The pen PN may transmit an output signal based on an electromagnetic resonance method. The pen PN may be referred to as an input device, an input pen, a magnetic pen, a stylus pen, or an electromagnetic resonance pen.

The pen PN may include an RLC resonant circuit, and the RLC resonant circuit may include an inductor L and a capacitor C. In an embodiment of the present disclosure, the RLC resonant circuit may be a variable resonant circuit that varies a resonant frequency. In this case, the inductor L may be a variable inductor and/or the capacitor C may be a variable capacitor, but the present disclosure is not particularly limited thereto.

The inductor L generates a current by a magnetic field formed in the electronic device 1000, for example, such as in the sensor layer 200. However, the present disclosure is not particularly limited thereto. For example, when the pen PN operates as an active kind, the pen PN may generate a current even though a magnetic field is not provided from the outside. The generated current is transmitted to the capacitor C. The capacitor C is charged by the current input from the inductor L, and discharges the stored current to the inductor L. Thereafter, the inductor L may emit a magnetic field at a resonant frequency. An induced current may flow in the sensor layer 200 by the magnetic field released by the pen PN, and the induced current may be transmitted to the sensor driver 200C as a reception signal (e.g., a sensing signal or a signal).

The main driver 1000C may control the overall operations of the electronic device 1000. For example, the main driver 1000C may control the operations of the display driver 100C and the sensor driver 200C. In other words, the main driver 1000C may control the operations of the display layer 100 and the sensor layer 200. The main driver 1000C may include at least one microprocessor, and may further include a graphic controller. The main driver 1000C may be referred to as an application processor, a central processing unit, or a main processor. The main driver 1000C may correspond to the processor 12 described above with reference to FIG. 1.

The display driver 100C may drive the display layer 100. The display driver 100C may receive image data and a control signal from the main driver 1000C. The control signal may include various suitable signals. For example, the control signal may include an input vertical synchronization signal, an input horizontal synchronization signal, a main clock signal, a data enable signal, and the like.

The sensor driver 200C may drive the sensor layer 200. The sensor driver 200C may receive a control signal from the main driver 1000C. The control signal may include a clock signal of the sensor driver 200C. In addition, the control signal may further include a mode determination signal that determines the driving modes of the sensor driver 200C and the sensor layer 200.

The sensor driver 200C may be implemented as an integrated circuit (IC), and may be electrically connected to the sensor layer 200. For example, the sensor driver 200C may be electrically connected to the sensor layer 200 by being directly mounted on a region (e.g., a predetermined region) of the display panel as an integrated circuit (IC), or by being mounted on a separate printed circuit board in a chip-on-film (COF) method.

The sensor driver 200C and the sensor layer 200 may selectively operate in a first mode or a second mode. For example, the first mode may be a mode for sensing a touch input, for example, such as the first input 2000. The second mode may be a mode for sensing a pen PN input, for example, such as the second input 3000. The first mode may be referred to as a touch sensing mode, and the second mode may be referred to as a pen sensing mode.

Conversion between the first mode and the second mode may be performed in various suitable ways. For example, the sensor driver 200C and the sensor layer 200 may be time-dividedly driven in the first mode and the second mode, and may sense the first input 2000 and the second input 3000. As another example, conversion between the first mode and the second mode may occur due to a selection or specific action of a user, or any one of the first mode or the second mode may be activated or deactivated, or converted into the other mode by activation or deactivation of a specific application. As another example, while the sensor driver 200C and the sensor layer 200 operate alternately in the first mode and the second mode, the first mode may be maintained when the first input 2000 is sensed, or the second mode may be maintained when the second input 3000 is sensed.

The sensor driver 200C may calculate the coordinate information of an input based on a signal received from the sensor layer 200, and may provide the main driver 1000C with a coordinate signal having the coordinate information. The main driver 1000C executes an operation corresponding to a user input based on the coordinate signal. For example, the main driver 1000C may operate the display driver 100C so that a new application image is displayed on the display layer 100.

The power circuit 1000P may include a power management integrated circuit (PMIC). The power circuit 1000P may generate a plurality of driving voltages for driving the display layer 100, the sensor layer 200, the display driver 100C, and the sensor driver 200C. For example, the plurality of driving voltages may include a gate high voltage, a gate low voltage, a first driving voltage, a second driving voltage, an initialization voltage, and the like, but the present disclosure is not particularly limited to the above examples.

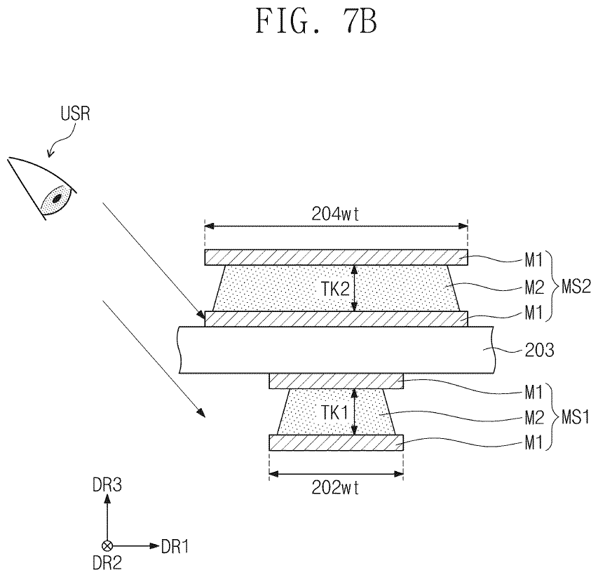

FIG. 7A is a cross-sectional view of the display panel DP according to an embodiment of the present disclosure.

Referring to FIG. 7A, at least one buffer layer BFL may be formed on the upper surface of the base layer 110. The buffer layer BFL may improve a bonding strength between the base layer 110 and the semiconductor pattern. The buffer layer BFL may be formed of a plurality of layers. As another example, the display layer 100 may further include a barrier layer. The buffer layer BFL may include at least one of silicon oxide, silicon nitride, or silicon oxynitride. For example, the buffer layer BFL may include a structure in which a silicon oxide layer and a silicon nitride layer are alternately stacked.

Semiconductor patterns SC, AL, DR, and SCL may be disposed on the buffer layer BFL. The semiconductor patterns SC, AL, DR, and SCL may include polysilicon. However, the present disclosure is not limited thereto, and the semiconductor patterns SC, AL, DR, and SCL may include amorphous silicon, a low-temperature polycrystalline silicon, or an oxide semiconductor.

FIG. 7A illustrates only some semiconductor patterns SC, AL, DR, and SCL, and additional semiconductor patterns may be disposed in other regions. The semiconductor patterns SC, AL, DR, and SCL may be arranged in a specific rule across pixels. The semiconductor patterns SC, AL, DR, and SCL may have different electrical properties depending on whether or not they are doped. The semiconductor patterns SC, AL, DR, and SCL may include a first region SC, DR, and SCL having a higher conductivity, and a second region AL having a lower conductivity. The first region SC, DR, and SCL may be doped with an N-type dopant or a P-type dopant. A P-type transistor may include a doped region doped with a P-type dopant, and an N-type transistor may include a doped region doped with an N-type dopant. The second region AL may be a non-doped region, or a region doped at a lower concentration than that of the first region SC, DR, and SCL.

The conductivity of the first region SC, DR, and SCL may be greater than that of the second region AL, and the first region SC, DR, and SCL may serve or substantially serve as an electrode or a signal line. The second region AL may correspond to or substantially correspond to an active region AL (e.g., a channel) of a transistor 100PC. In other words, a portion AL of the semiconductor patterns SC, AL, DR, and SCL may be an active region AL of the transistor 100PC, another portion SC and DR thereof may be a source region SC or drain region DR of the transistor 100PC, and still another portion SCL thereof may be a connection electrode or a connection signal line SCL.

Each of the pixels may have an equivalent circuit including a plurality of transistors, at least one capacitor, and at least one light-emitting element, but the equivalent circuit diagram of the pixel may be modified in various suitable forms. FIG. 7A illustrates one transistor 100PC and a light-emitting element 100PE included in the pixel.

The source region SC, the active region AL, and the drain region DR of the transistor 100PC may be formed from the semiconductor patterns SC, AL, DR, and SCL. The source region SC and the drain region DR may extend in opposite directions from each other from the active region AL on a cross section. FIG. 7A illustrates a portion of the connection signal line SCL formed from the semiconductor patterns SC, AL, DR, and SCL. In another view, the connection signal line SCL may be connected to the drain region DR of the transistor 100PC on a plane (e.g., in a plan view).

A first insulating layer 10 may be disposed on the buffer layer BFL. The first insulating layer 10 may commonly overlap with a plurality of pixels, and may cover the semiconductor patterns SC, AL, DR, and SCL. The first insulating layer 10 may be an inorganic layer and/or an organic layer, and may have a single-layer or multi-layered structure. The first insulating layer 10 may include at least one of aluminum oxide, titanium oxide, silicon oxide, silicon nitride, silicon oxynitride, zirconium oxide, or hafnium oxide. In the present embodiment, the first insulating layer 10 may be a single layer of silicon oxide. Not only the first insulating layer 10, but also the insulating layers of the circuit layer 120 to be described in more detail below, may be an inorganic layer and/or an organic layer, and may have a single-layer or multi-layered structure. The inorganic layer may include at least one of the above-mentioned materials, but the present disclosure is not limited thereto.

A gate GT of the transistor 100PC is disposed on the first insulating layer 10. The gate GT may be a portion of a metal pattern. The gate GT overlaps with the active region AL. In a process of doping or reducing the semiconductor patterns SC, AL, DR, and SCL, the gate GT may function as a mask.

A second insulating layer 20 may be disposed on the first insulating layer 10, and may cover the gate GT. The second insulating layer 20 may commonly overlap with the pixels. The second insulating layer 20 may be an inorganic layer and/or an organic layer, and may have a single-layer or multi-layered structure. The second insulating layer 20 may include at least one of silicon oxide, silicon nitride, or silicon oxynitride. In the present embodiment, the second insulating layer 20 may have a multi-layered structure including a silicon oxide layer and a silicon nitride layer.

A third insulating layer 30 may be disposed on the second insulating layer 20. The third insulating layer 30 may have a single-layer or multi-layered structure. For example, the third insulating layer 30 may have a multi-layered structure including a silicon oxide layer and a silicon nitride layer.

A first connection electrode CNE1 may be disposed on the third insulating layer 30. The first connection electrode CNE1 may be connected to the connection signal line SCL through a contact hole CNT-1 passing through (e.g., penetrating) the first, second, and third insulating layers 10, 20, and 30.

A fourth insulating layer 40 may be disposed on the third insulating layer 30. The fourth insulating layer 40 may be a single layer of silicon oxide. A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected to the first connection electrode CNE1 through a contact hole CNT-2 passing through (e.g., penetrating) the fourth insulating layer 40 and the fifth insulating layer 50.

A sixth insulating layer 60 may be disposed on the fifth insulating layer 50, and may cover the second connection electrode CNE2. The sixth insulating layer 60 may be an organic layer.

The light-emitting element layer 130 may be disposed on the circuit layer 120. The light-emitting element layer 130 may include a light-emitting element 100PE. For example, the light-emitting element layer 130 may include an organic light-emitting material, an inorganic light-emitting material, an organic-inorganic light-emitting material, quantum dots, quantum rods, micro LEDs, or nano LEDs. Hereinafter, the light-emitting element 100PE will be described in more detail as an organic light-emitting element, but the present disclosure is not particularly limited thereto.

The light-emitting element 100PE may include a first electrode AE, a light-emitting layer EL, and a second electrode CE. The light-emitting element 100PE may be disposed in the display region 100A (e.g., see FIG. 5). The first electrode AE may be referred to as a pixel electrode, and the second electrode CE may be referred to as a common electrode.

The first electrode AE may be disposed on the sixth insulating layer 60. The first electrode AE may be connected to the second connection electrode CNE2 through a contact hole CNT-3 passing through (e.g., penetrating) the sixth insulating layer 60.

A pixel defining film 70 may be disposed on the sixth insulating layer 60, and may cover a portion of the first electrode AE. An opening 70-OP is defined in the pixel defining film 70. The opening 70-OP of the pixel defining film 70 exposes at least a portion of the first electrode AE.

The display region 100A (e.g., see FIG. 5) may include a light-emitting region PXA, and a non-light-emitting region NPXA adjacent to the light-emitting region PXA. The non-light-emitting region NPXA may surround (e.g., around a periphery of) the light-emitting region PXA. In the present embodiment, the light-emitting region PXA is defined to correspond to a partial region of the first electrode AE exposed by the opening 70-OP.

The light-emitting layer EL may be disposed on the first electrode AE. The light-emitting layer EL may be disposed in a region corresponding to the opening 70-OP. FIG. 7A illustrates that the light-emitting layer EL is disposed in the opening 70-OP, but the present disclosure is not particularly limited thereto. For example, the light-emitting layer EL may extend to cover a portion of the side and upper surfaces of the pixel defining film 70 defining the opening 70-OP.

In an embodiment of the present disclosure, the light-emitting layer EL may be separately included in each pixel. When the light-emitting layer EL is separately formed in each pixel, each of the light-emitting layers EL may emit light of at least one color among blue, red, and/or green. However, the present disclosure is not limited thereto, and the light-emitting layer EL may have an integrated shape to be commonly included in a plurality of pixels. In this case, the light-emitting layer EL may provide blue light or white light.

The second electrode CE may be disposed on the light-emitting layer EL. The second electrode CE may have an integrated shape, and may be commonly included in a plurality of pixels.

In an embodiment of the present disclosure, a hole control layer may be disposed between the first electrode AE and the light-emitting layer EL. The hole control layer may be commonly disposed in the light-emitting region PXA and the non-light-emitting region NPXA. The hole control layer may include a hole transport layer, and may further include a hole injection layer as needed or desired. An electron control layer may be disposed between the light-emitting layer EL and the second electrode CE. The electron control layer may include an electron transport layer, and may further include an electron injection layer as needed or desired. The hole control layer and the electron control layer may be commonly formed in a plurality of pixels by using an open mask or an inkjet process.

The encapsulation layer 140 may be disposed on the light-emitting element layer 130. The encapsulation layer 140 may include an inorganic layer, an organic layer, and an inorganic layer that are sequentially stacked, but the layers constituting the encapsulation layer 140 are not limited thereto. The inorganic layers may protect the light-emitting element layer 130 from moisture and oxygen, and the organic layer may protect the light-emitting element layer 130 from foreign substances such as dust particles. The inorganic layers may include a silicon nitride layer, a silicon oxynitride layer, a silicon oxide layer, a titanium oxide layer, an aluminum oxide layer, or the like. The organic layer may include an acrylic-based organic layer, but the present disclosure is not limited thereto.

The sensor layer 200 may include a base layer 201, a first conductive layer 202, an intermediate insulating layer 203, a second conductive layer 204, and a cover insulating layer 205.

The base layer 201 may be an inorganic layer including at least any one of silicon nitride, silicon oxynitride, or silicon oxide. As another example, the base layer 201 may be an organic layer including an epoxy resin, an acrylic resin, or an imide-based resin. The base layer 201 may have a single-layer structure, or a multi-layered structure in which layers are stacked along the third direction DR3. In an embodiment of the present disclosure, the sensor layer 200 may not include the base layer 201.

Each of the first conductive layer 202 and the second conductive layer 204 may have a single-layer structure, or a multi-layered structure in which layers are stacked along the third direction DR3.

Each of the first conductive layer 202 and the second conductive layer 204 having a single-layer structure may include a metal layer or a transparent conductive layer. The metal layer may include molybdenum, silver, titanium, copper, aluminum, or a suitable alloy thereof. The transparent conductive layer may include a transparent conductive oxide, such as indium tin oxide (ITO), indium zinc oxide (IZO), zinc oxide (ZnO), or indium zinc tin oxide (IZTO). In addition, the transparent conductive layer may include a conductive polymer, such as poly(3,4-ethylenedioxythiophene) (PEDOT), a metal nanowire, graphene, and/or the like.

Each of the first conductive layer 202 and the second conductive layer 204 having a multi-layered structure may include a plurality of metal layers. The metal layers may have a three-layered structure of, for example, titanium/aluminum/titanium. The conductive layer having a multi-layered structure may include at least one metal layer and at least one transparent conductive layer.

In an embodiment of the present disclosure, the thickness of the first conductive layer 202 may be greater than or equal to the thickness of the second conductive layer 204. When the thickness of the first conductive layer 202 is greater than the thickness of the second conductive layer 204, a resistance of the components (e.g., an electrode, a pattern, a bridge pattern, or the like) included in the first conductive layer 202 may be reduced. In addition, because the first conductive layer 202 may be disposed below the second conductive layer 204, a probability that the components included in the first conductive layer 202 are viewed due to an external light reflection may be lower than that of the second conductive layer 204, even though the thickness of the first conductive layer 202 is increased.

At least any one of the intermediate insulating layer 203 or the cover insulating layer 205 may include an inorganic film. The inorganic film may include at least one of aluminum oxide, titanium oxide, silicon oxide, silicon nitride, silicon oxynitride, zirconium oxide, or hafnium oxide.

At least any one of the intermediate insulating layer 203 or the cover insulating layer 205 may include an organic film. The organic film may include at least any one of an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

As described above, the sensor layer 200 includes the first conductive layer 202 and the second conductive layer 204, or in other words, two conductive layers in total, but the present disclosure is not particularly limited thereto. For example, the sensor layer 200 may include three or more conductive layers.

FIG. 7B is a cross-sectional view illustrating a partial configuration of the sensor layer 200 (e.g., see FIG. 7A) according to an embodiment of the present disclosure.

Referring to FIGS. 7A and 7B, a second width 204wt of a second mesh line MS2 included in the second conductive layer 204 may be greater than or equal to a first width 202wt of a first mesh line MS1 included in the first conductive layer 202. When a user USR views the first mesh line MS1 and the second mesh line MS2 from a side, the first mesh line MS1 may have a smaller width than that of the second mesh line MS2, so a probability that the first mesh line MS1 is viewed by the user USR may be reduced.

Each of the first mesh line MS1 and the second mesh line MS2 may include first metal layers M1, and a second metal layer M2 disposed between the first metal layers M1. For example, the first metal layers M1 may include titanium (Ti), and the second metal layer M2 may include aluminum (Al). However, the present disclosure is not particularly limited thereto.

In an embodiment of the present disclosure, a first thickness TK1 of the second metal layer M2 of the first mesh line MS1 and a second thickness TK2 of the second metal layer M2 of the second mesh line MS2 may be the same or substantially the same as each other, but the present disclosure is not particularly limited thereto. For example, the first thickness TK1 may be greater than the second thickness TK2. As another example, the second thickness TK2 may be greater than the first thickness TK1. In an embodiment of the present disclosure, each of the first thickness TK1 and the second thickness TK2 may be about 1000 angstroms or more, for example, such as about 6000 angstroms.

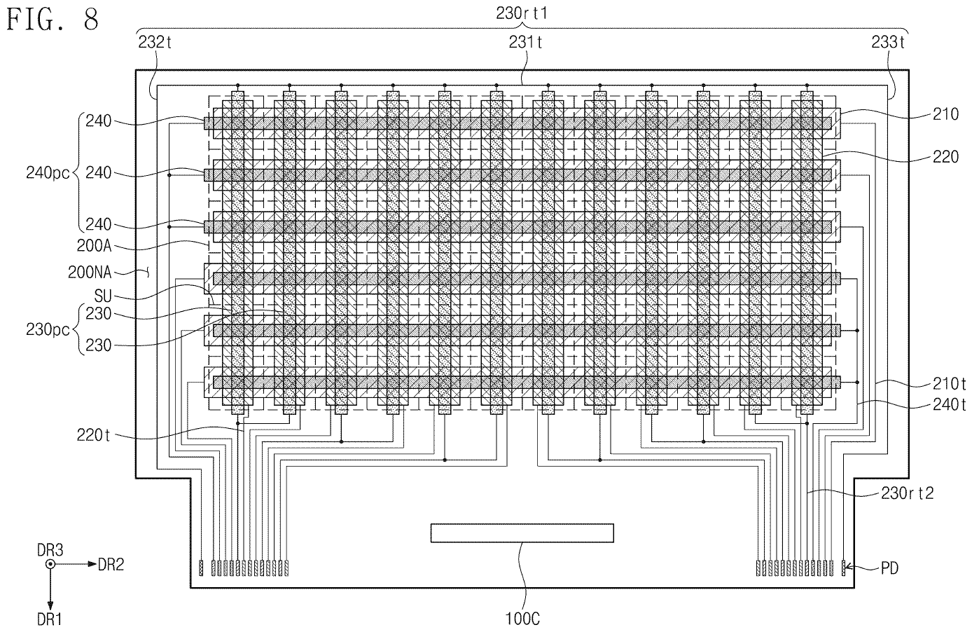

FIG. 8 is a plan view of the sensor layer 200 according to an embodiment of the present disclosure.

Referring to FIG. 8, a sensing region 200A and a peripheral region 200NA adjacent to the sensing region 200A may be defined in the sensor layer 200.

The sensor layer 200 may include a plurality of first electrodes 210, a plurality of second electrodes 220, a plurality of third electrodes 230, and a plurality of fourth electrodes 240 disposed in the sensing region 200A.

Each of the first electrodes 210 may cross the second electrodes 220. Each of the first electrodes 210 may extend along the second direction DR2, and the first electrodes 210 may be spaced apart from each other in the first direction DR1. Each of the second electrodes 220 may extend along the first direction DR1, and the second electrodes 220 may be spaced apart from each other in the second direction DR2.

The sensing region 200A of the sensor layer 200 may include a plurality of sensing units SU arranged along the first direction DR1 and the second direction DR2. Each of the sensing units SU may be a region in which one corresponding first electrode 210 and one corresponding second electrode 220 cross each other.

FIG. 8 illustrates six first electrodes 210 and twelve second electrodes 220, and illustrates seventy-two sensing units SU, but the number of first electrodes 210 and the number of second electrodes 220 are not limited thereto.

Each of the third electrodes 230 may extend along the first direction DR1, and the third electrodes 230 may be spaced apart from each other in the second direction DR2. One third electrode 230 may at least partially overlap with one second electrode 220. According to an embodiment of the present disclosure, by adjusting the overlapping area of one second electrode 220 and one third electrode 230, the capacitance (e.g., a coupling capacitance) between the second electrode 220 and the third electrode 230 may be controlled.

In an embodiment of the present disclosure, at least some of the third electrodes 230 may be connected in parallel with each other. For example, FIG. 8 illustrates that two third electrodes 230 are connected in parallel with each other to form a first electrode group 230pc, and six first electrode groups 230pc may be arranged along the first direction DR1. However, the number of third electrodes 230 forming the first electrode group 230pc is not limited thereto. For example, one first electrode group 230pc may include only one third electrode 230, or may include three or more third electrodes 230.

As the number of third electrodes 230 included in the first electrode group 230pc and connected in parallel with each other increases, the resistance of the first electrode group 230pc decreases, and thus, a power efficiency and a sensing sensitivity may be improved. On the other hand, as the number of third electrodes 230 included in the first electrode group 230pc decreases, a loop coil pattern formed by using the first electrode group 230pc may be implemented in more diverse forms.

The fourth electrodes 240 may be arranged along the first direction DR1, and may extend along the second direction DR2. One fourth electrode 240 may at least partially overlap with one first electrode 210. According to an embodiment of the present disclosure, by adjusting the overlapping area of one first electrode 210 and one fourth electrode 240, the capacitance (e.g., the coupling capacitance) between the first electrode 210 and the fourth electrode 240 may be controlled.

In an embodiment of the present disclosure, at least some of the fourth electrodes 240 may be electrically connected to each other to form one second electrode group 240pc. For example, FIG. 8 illustrates that three fourth electrodes 240 are connected to one same trace line, for example, to an auxiliary trace line 240t to form one second electrode group 240pc. Accordingly, FIG. 8 illustrates that two second electrode groups 240pc are arranged along the second direction DR2. However, the number of fourth electrodes 240 forming one second electrode group 240pc is not limited thereto. For example, the number of fourth electrodes 240 forming one second electrode group 240pc may be six, and in this case, the sensor layer 200 may include only one second electrode group 240pc.

The sensor layer 200 may further include a plurality of first trace lines 210t and a plurality of second trace lines 220t disposed in the peripheral region 200NA. The first trace lines 210t may be electrically connected to each of the first electrodes 210 in a one-to-one correspondence. The second trace lines 220t may be electrically connected to each of the second electrodes 220 in a one-to-one correspondence.

The sensor layer 200 may further include a first loop trace line 230rt1, auxiliary trace lines 240t, and second loop trace lines 230rt2 disposed in the peripheral region 200NA. The first loop trace line 230rt1 may be referred to as a loop trace line, the second loop trace lines 230rt2 may be referred to as third trace lines, and the auxiliary trace lines 240t may be referred to as fourth trace lines.

In an embodiment of the present disclosure, the first loop trace line 230rt1 may be electrically connected to the third electrodes 230. In other words, the first loop trace line 230rt1 may be electrically connected to all of the third electrodes 230. The third electrodes 230 may be referred to as charging electrodes.

The first loop trace line 230rt1 may include a first line portion 231t extending along the second direction DR2 and electrically connected to the third electrodes 230, a second line portion 232t extending along the first direction DR1 from a first end of the first line portion 231t, and a third line portion 233t extending along the first direction DR1 from a second end of the first line portion 231t.

Each of the second line portion 232t and the third line portion 233t may extend in the same direction as that of the extension direction of the third electrodes 230, for example, such as in the first direction DR1. Each of the second line portion 232t and the third line portion 233t may serve as the first electrode group 230pc, and the same effect as having the third electrodes 230 also disposed in the peripheral region 200NA may be achieved. For example, any one of the second line portion 232t or the third line portion 233t, or any one of the third electrodes 230 may form a coil. Accordingly, a pen located in a region adjacent to the peripheral region 200NA may also be sufficiently charged by a loop including the second line portion 232t or the third line portion 233t.

In an embodiment of the present disclosure, in order to control the resistance of the second line portion 232t and the resistance of the third line portion 233t, the position and the width in the first direction DR1 of each of the second line portion 232t and the third line portion 233t may be adjusted. In this case, a pen may also be sufficiently charged through a current path including the second line portion 232t or the third line portion 233t. As a result, a pen charging performance of the electronic device 1000 (e.g., see FIG. 2A) may be improved. In other words, as a charging rate of the pen is improved, the signal-to-noise ratio of a signal provided from the pen may increase. Accordingly, the linearity and accuracy of the pen input may be improved.

The second loop trace lines 230rt2 may be respectively connected to the first electrode groups 230pc in a one-to-one correspondence. In other words, the number of the second loop trace lines 230rt2 may correspond to the number of the first electrode groups 230pc. FIG. 8 illustrates six second loop trace lines 230rt2 and six first electrode groups 230pc.

The auxiliary trace lines 240t may be spaced apart from each other with the sensing region 200A interposed between the auxiliary trace lines 240t. The auxiliary trace lines 240t may be electrically connected to the second electrode groups 240pc in a one-to-one correspondence. FIG. 8 illustrates that two second electrode groups 240pc are arranged. The auxiliary trace line 240t connected to one second electrode group 240pc and the auxiliary trace line 240t connected to another second electrode group 240pc may be spaced apart from each other with the sensing region 200A interposed between the auxiliary trace lines 240t. However, the present disclosure is not particularly limited thereto. The auxiliary trace lines 240t may also be referred to as trace lines.

The sensor layer 200 may further include a plurality of pads PD electrically connected to the first trace lines 210t, the second trace lines 220t, one end and another end (e.g., an opposite end) of the first loop trace line 230rt1, the second loop trace lines 230rt2, and the auxiliary trace lines 240t in a one-to-one correspondence. The pads PD may be spaced apart from each other in the second direction DR2. FIG. 8 illustrates that the pads PD are arranged in one row, but the present disclosure is not particularly limited thereto. For example, the pads PD may be arranged in multiple rows.

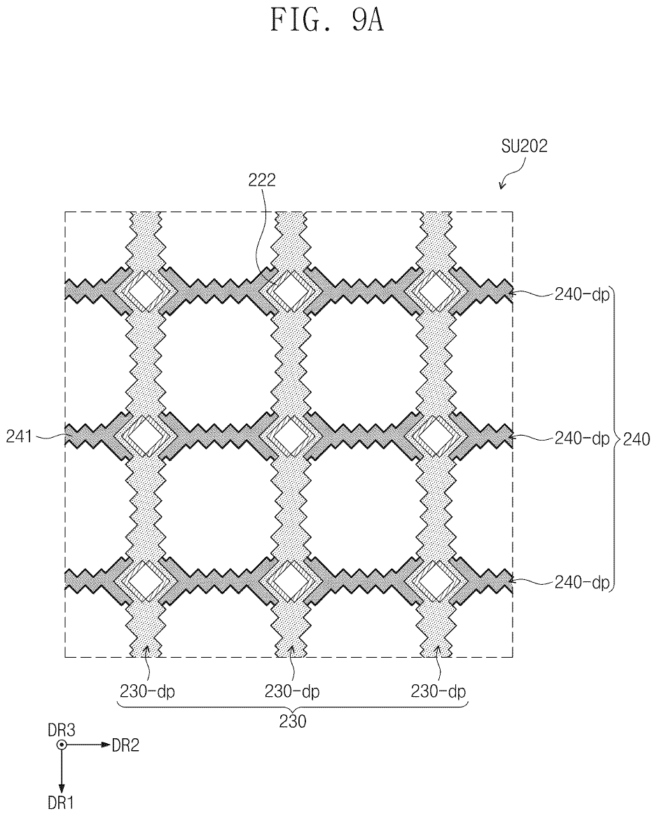

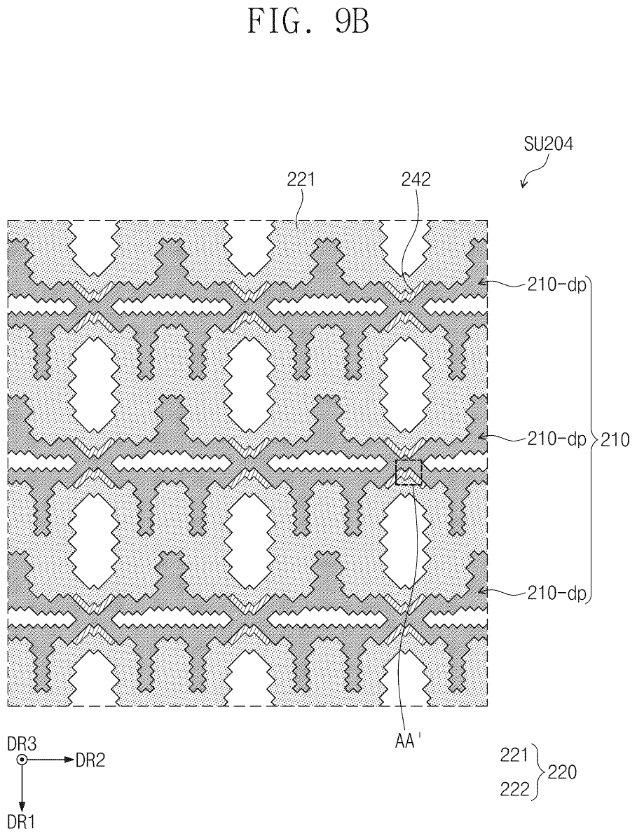

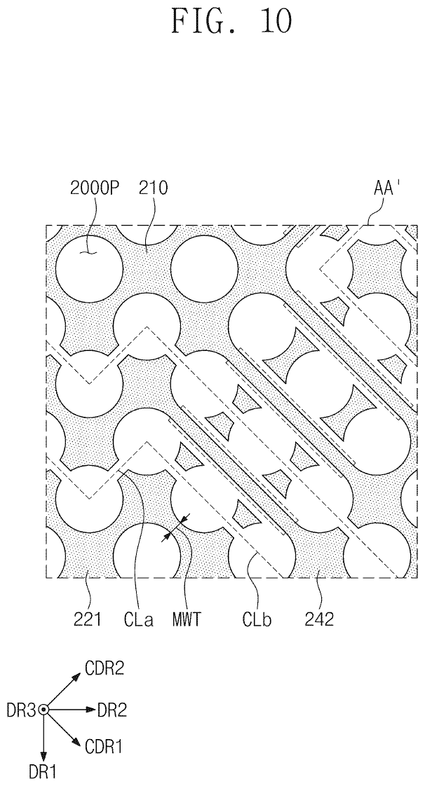

FIG. 9A is a plan view illustrating a first conductive layer SU202 of a sensing unit SU (e.g., see FIG. 8) according to an embodiment of the present disclosure. FIG. 9B is a plan view illustrating a second conductive layer SU204 of the sensing unit SU (e.g., see FIG. 8) according to an embodiment of the present disclosure. FIG. 10 is an enlarged plan view of the region AA′ illustrated in FIG. 9B.

In FIGS. 9A and 9B, the shape of the mesh structure is not illustrated, and the boundaries of each component are simply illustrated by lines. In other words, the lines illustrated in FIGS. 9A and 9B may be understood as corresponding to the lines illustrated in FIG. 10 in which the mesh structure is removed, and the lines CLa and CLb are illustrated as dashed lines in FIG. 10.

The shape and the mesh structure of the sensing unit SU illustrated in FIGS. 9A, 9B, and 10 are provided as examples, and the present disclosure is not limited thereto. The shape and the mesh structure of the sensing unit SU may be modified in various suitable ways as needed or desired.

Referring to FIGS. 9A and 9B, the first electrode 210 may include a plurality of first split electrodes 210-dp spaced apart from each other in the first direction DR1. Each of the first split electrodes 210-dp may extend in the second direction DR2, and the first split electrodes 210-dp may be spaced apart from each other in the first direction DR1. The first split electrodes 210-dp may be included in the second conductive layer SU204. Three first split electrodes 210-dp included in one first electrode 210 may be connected to one first trace line 210t (e.g., see FIG. 8).

The second electrode 220 may include a plurality of first patterns 221, and a plurality of first bridge patterns 222 electrically connected to the first patterns 221. The first patterns 221 spaced apart from each other in the first direction DR1 may be electrically connected to each other by the first bridge patterns 222. The first patterns 221 may be included in the second conductive layer SU204, and the first bridge patterns 222 may be included in the first conductive layer SU202.

Two first patterns 221 adjacent to each other in the first direction DR1 in one second electrode 220 may be electrically connected to each other by six first bridge patterns 222. An increase in the number of the first bridge patterns 222 arranged in the second direction DR2 crossing the first direction DR1, which is the extension direction of the second electrode 220, may correspond to an increase in the number of signal paths. Therefore, as the number of signal paths increases, the resistance of the second electrode 220 may decrease. As a result, the sensing sensitivity of the sensor layer 200 may be improved.

The third electrode 230 may include a plurality of second split electrodes 230-dp spaced apart from each other in the second direction DR2. Each of the second split electrodes 230-dp may extend along the first direction DR1. The second split electrodes 230-dp may be spaced apart from each other in the second direction DR2. When viewed in the third direction DR3 (e.g., in a plan view), the second split electrodes 230-dp may at least partially overlap with the first patterns 221.

Referring to FIGS. 8 and 9A together, one second loop trace line 230rt2 is electrically connected to one first electrode group 230pc. One first electrode group 230pc may include two third electrodes 230. In this case, one second loop trace line 230rt2 may be electrically connected to six second split electrodes 230-dp. In this case, a degree to which the number of pads in the sensor layer 200 increases may be reduced.

The fourth electrode 240 may include a plurality of third split electrodes 240-dp spaced apart from each other in the first direction DR1. Each of the third split electrodes 240-dp may extend along the second direction DR2. Each of the third split electrodes 240-dp may include a plurality of second patterns 241, and a plurality of second bridge patterns 242 electrically connected to the second patterns 241. The second patterns 241 and the second bridge patterns 242 may be electrically connected to each other through contact holes defined in the first insulating layer 203 (e.g., see FIG. 7A). Two adjacent second patterns 241 may be spaced apart from each other with one second split electrode 230-dp and two first bridge patterns 222 interposed between the two adjacent second patterns 241.

FIGS. 9A and 9B illustrate that one sensing unit SU includes three first split electrodes 210-dp, three second split electrodes 230-dp, and three third split electrodes 240-dp, but the present disclosure is not particularly limited thereto. For example, each of the number of first split electrodes 210-dp, the number of second split electrodes 230-dp, and the number of third split electrodes 240-dp included in one sensing unit SU may be one, two, or four or more.

In an embodiment of the present disclosure, a first capacitor may be defined between the first electrode 210 and the fourth electrode 240, and a second capacitor may be defined between the second electrode 220 and the third electrode 230. A first capacitance of the first capacitor and a second capacitance of the second capacitor may be controlled by the overlapping area of the first electrode 210 and the fourth electrode 240, and the overlapping area of the second electrode 220 and the third electrode 230.

As the first and second capacitances increase, an amount of induced current transferred from the fourth electrode 240 to the first electrode 210 may increase, and an amount of induced current transferred from the third electrode 230 to the second electrode 220 may increase. Accordingly, as the first and second capacitances increase, a pen sensing performance of the sensor layer 200 may be improved. In addition, the first and second capacitances may act as a load during touch sensing. Accordingly, as the first and second capacitances decrease, the touch sensing performance may be improved.

In an embodiment of the present disclosure, the overlapping area of the first electrode 210 and the fourth electrode 240 and the overlapping area of the second electrode 220 and the third electrode 230 may be easily controlled. Accordingly, the sensor layer 200 having capacitances at appropriate levels considering a touch sensitivity and a pen sensing sensitivity may be provided. As a result, the electronic device 1000 (e.g., see FIG. 2A) having an improved pen sensitivity and an improved touch sensitivity may be provided.

In an embodiment of the present disclosure, in the second conductive layer SU204 in one sensing unit SU, the area occupied by the components included in the first electrode 210 and the second electrode 220 may be larger than the area occupied by the components included in the third electrode 230 and the fourth electrode 240. A change in capacitance due to the first input 2000 (e.g., see FIG. 4) may be larger as a distance is closer. Therefore, a component for sensing the first input 2000 (e.g., see FIG. 4) may be disposed with a larger area in a layer relatively more adjacent to the surface of the electronic device 1000 (e.g., see FIG. 1A). As a result, a touch performance may be improved.

Referring to FIGS. 9A, 9B, and 10, each of the first to fourth electrodes 210, 220, 230, and 240 may have a mesh structure. The mesh structure may be a structure in which a plurality of openings 200OP are defined. In FIG. 10, each of the plurality of openings 200OP is illustrated as having a circular shape with a suitable curvature (e.g., a predetermined curvature), but the present disclosure is not particularly limited thereto. For example, each of the openings 200OP may be variously modified to have various suitable shapes, such as a square, a polygon, a diamond, or an atypical shape.

FIG. 10 illustrates portions of the first pattern 221, the second bridge pattern 242, and the first electrode 210 disposed in the second conductive layer SU204. The first pattern 221, the second bridge pattern 242, and the first electrode 210 may be electrically insulated from each other. For example, the first pattern 221, the second bridge pattern 242, and the first electrode 210 may be electrically insulated from each other by a first line CLa and a second line CLb. A portion and another portion of the conductive layer may be spaced apart from each other with the first line CLa and the second line CLb interposed between them. The second line CLb may extend along a first crossing direction CDR1 crossing the first direction DR1 and the second direction DR2, and the first line CLa may extend along a second crossing direction CDR2 crossing the first crossing direction CDR1.

A line width MWT of the mesh structure may correspond to the width between the openings 200OP defined in the mesh structure. For example, the line width MWT may correspond to a minimum width of the conductive layer disposed between two most adjacent openings 200OP among the openings 200OP.

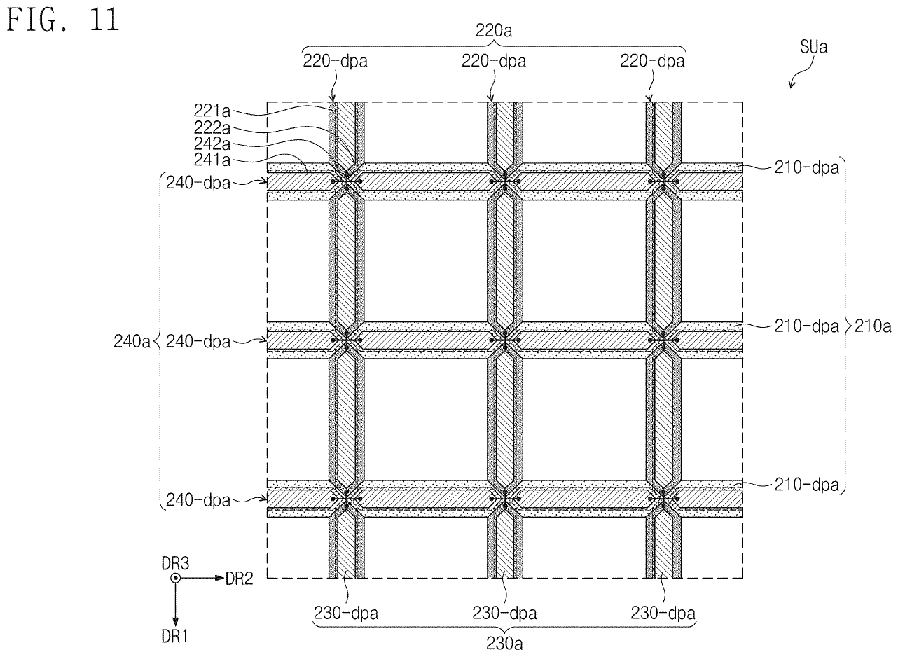

FIG. 11 is a plan view illustrating a sensing unit SUa according to an embodiment of the present disclosure.

Referring to FIG. 11, a portion of a first electrode 210a, a portion of a second electrode 220a, a portion of a third electrode 230a, and a portion of a fourth electrode 240a, which overlap with one sensing unit SUa, are illustrated.

The first electrode 210a may include a plurality of first split electrodes 210-dpa spaced apart from each other in the first direction DR1. The second electrode 220a may include a plurality of second split electrodes 220-dpa spaced apart from each other in the second direction DR2. The third electrode 230a may include a plurality of third split electrodes 230-dpa spaced apart from each other in the second direction DR2. The fourth electrode 240a may include a plurality of fourth split electrodes 240-dpa spaced apart from each other in the first direction DR1.

Each of the second split electrodes 220-dpa may include first patterns 221a and first bridge patterns 222a. Each of the fourth split electrodes 240-dpa may include second patterns 241a and second bridge patterns 242a.

The first split electrodes 210-dpa, the first patterns 221a, and the second bridge patterns 242a may be included in the second conductive layer 204 (e.g., see FIG. 7A). The third split electrodes 230-dpa, the second patterns 241a, and the first bridge patterns 222a may be included in the first conductive layer 202 (e.g., see FIG. 7A). The first bridge pattern 222a may be insulated from and cross the second bridge pattern 242a and the first split electrode 210-dpa.

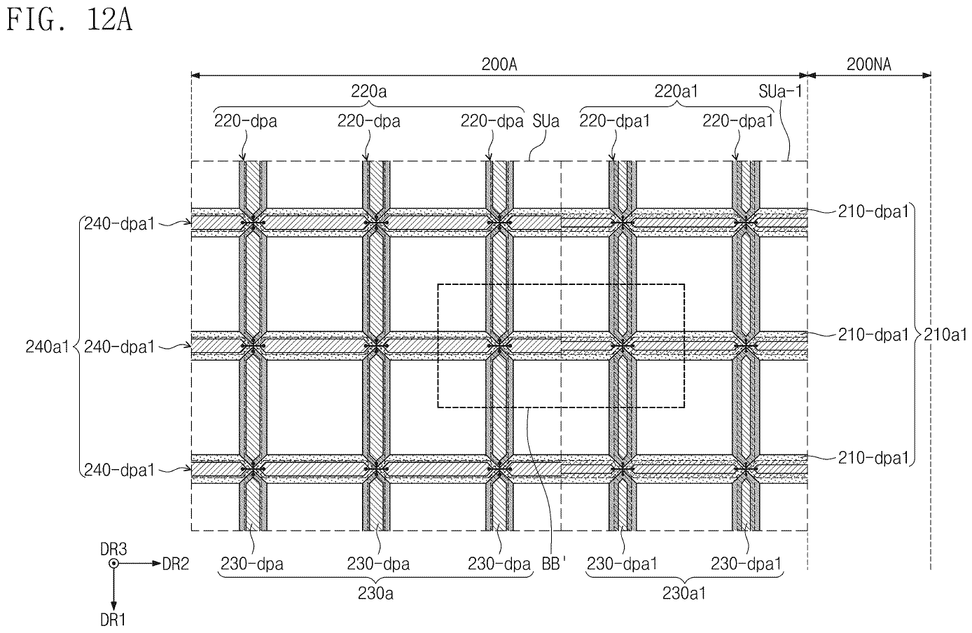

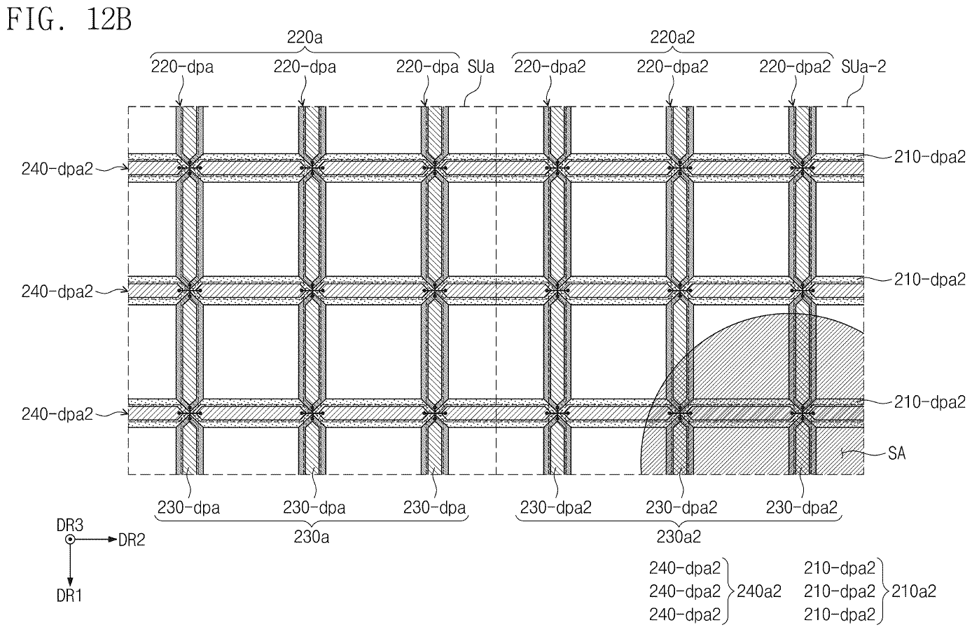

FIG. 12A is a plan view illustrating two sensing units according to an embodiment of the present disclosure.

Referring to FIG. 8 and FIG. 12A, the sensing units SU may include a first sensing unit SUa and a second sensing unit SUa-1. The first sensing unit SUa may be spaced apart from the peripheral region 200NA, and the second sensing unit SUa-1 may be in contact with the peripheral region 200NA. In other words, the second sensing unit SUa-1 may be closer to the peripheral region 200NA than the first sensing unit SUa.

The first electrodes 210 may include a first electrode 210a1 overlapping with the first sensing unit SUa and the second sensing unit SUa-1. The second electrodes 220 may include a (2-1)-th electrode 220a overlapping with the first sensing unit SUa, and a (2-2)-th electrode 220a1 overlapping with the second sensing unit SUa-1. The third electrodes 230 may include a (3-1)-th electrode 230a overlapping with the first sensing unit SUa, and a (3-2)-th electrode 230a1 overlapping with the second sensing unit SUa-1. The fourth electrodes 240 may include a fourth electrode 240a1 overlapping with the first sensing unit SUa and the second sensing unit SUa-1.

In an embodiment of the present disclosure, the shape of the second sensing unit SUa-1 may be different from the shape of the first sensing unit SUa. For example, the width of the second sensing unit SUa-1 in the second direction DR2 may be smaller than the width of the first sensing unit SUa in the second direction DR2. The second sensing unit SUa-1 may have various suitable shapes different from that of the first sensing unit SUa, and is not limited to having a specific shape. For example, when the boundary between the sensing region 200A and the peripheral region 200NA has a curvature, the second sensing unit SUa-1 may be in contact with the boundary having the curvature, and may have a shape from which the shapes of some electrodes are removed.

In an embodiment of the present disclosure, the (2-1)-th electrode 220a may include x first split electrodes 220-dpa spaced apart from each other along the second direction DR2. The (2-2)-th electrode 220a1 may include y second split electrodes 220-dpa1 spaced apart from each other along the second direction DR2. The x and the y may be integers greater than or equal to 1. In an embodiment of the present disclosure, the x may be greater than the y. FIG. 12A illustrates that the x is 3 and the y is 2.

According to an embodiment of the present disclosure, in order to improve a pen sensing performance, the shapes of portions of the first to fourth electrodes 210a1, 220a1, 230a1, and 240a1 overlapping with the second sensing unit SUa-1 may be adjusted. For example, because the area of the second sensing unit SUa-1 is smaller than that of the first sensing unit SUa, the shapes (or areas) of portions of the first to fourth electrodes 210a1, 220a1, 230a1, and 240a1 may be designed to be different from those of the first sensing unit SUa, so that a capacitance of a capacitor formed between the first electrode 210a1 and the fourth electrode 240a1 and a capacitance of a capacitor formed between the second electrode 220a1 and the third electrode 230a1, which are reduced to that extent, are increased. In this case, a detected signal due to a smaller size of the second sensing unit SUa-1 may be compensated for by an increase in the capacitance resulting from the adjustment of the shapes of portions of the first to fourth electrodes 210a1, 220a1, 230a1, and 240a1. Therefore, the sensing performance of the sensor layer 200, especially at the outer portion of the sensing region 200A, may be improved.

In an embodiment of the present disclosure, the (3-1)-th electrode 230a may include x third split electrodes 230-dpa overlapping with the first split electrodes 220-dpa in a one-to-one correspondence, and spaced apart from each other along the second direction DR2. The (3-2)-th electrode 230a1 may include y fourth split electrodes 230-dpa1 overlapping with the second split electrodes 220-dpa1 in a one-to-one correspondence, and spaced apart from each other along the second direction DR2.

In an embodiment of the present disclosure, the shape of a first overlapping region in which one first split electrode 220-dpa and one third split electrode 230-dpa overlap with each other may be different from the shape of a second overlapping region in which one second split electrode 220-dpa1 and one fourth split electrode 230-dpa1 overlap with each other. For example, in order to increase the reduced capacitance of the second sensing unit SUa-1 having a reduced size, the area of the second overlapping region may be larger than the area of the first overlapping region. Accordingly, the shape of the overlapping region of the (2-1)-th electrode 220a and the (3-1)-th electrode 230a and the shape of the overlapping region of the (2-2)-th electrode 220a1 and the (3-2)-th electrode 230a1 may be different from each other.

In addition, in an embodiment of the present disclosure, the first electrode 210a1 may include fifth split electrodes 210-dpa1 spaced apart from each other along the first direction DR1, and the fourth electrode 240a1 may include sixth split electrodes 240-dpa1 spaced apart from each other along the first direction DR1. The shapes of the portions of the fifth split electrodes 210-dpa1 or the sixth split electrodes 240-dpa1 overlapping with the first sensing unit SUa may be different from those overlapping with the second sensing unit SUa1. For example, the areas of the fifth split electrodes 210-dpa1 or the sixth split electrodes 240-dpa1 may be variously modified in order to increase the reduced capacitance of the second sensing unit SUa-1 having a reduced size.

FIG. 12B is a plan view illustrating two sensing units according to an embodiment of the present disclosure.

Referring to FIG. 8 and FIG. 12B, the sensing units SU may include a first sensing unit SUa and a second sensing unit SUa-2. The first sensing unit SUa may be spaced apart from the peripheral region 200NA, and the second sensing unit SUa-2 may overlap with a module region SA. The module region SA may be a region overlapping with a sensor or an electronic module (e.g., an electronic sensor), for example, such as a camera module (e.g., a camera). A portion of the sensing region 200A overlapping with the module region SA may have a higher transmittance than that of another portion of the sensing region 200A that does not overlap with the module region SA. Accordingly, the density of the mesh structure of a portion of the electrodes overlapping with the module region SA may be lower than the density of the mesh structure of a portion of the electrodes non-overlapping with the module region SA. In addition, unlike that illustrated in FIG. 12B, a portion of the electrodes may be omitted in the portion overlapping with the module region SA.

The first electrodes 210 may include a first electrode 210a2 overlapping with the first sensing unit SUa and the second sensing unit SUa-2, and the second electrodes 220 may include a (2-1)-th electrode 220a overlapping with the first sensing unit SUa and a (2-2)-th electrode 220a2 overlapping with the second sensing unit SUa-2. The third electrodes 230 may include a (3-1)-th electrode 230a overlapping with the first sensing unit SUa and a (3-2)-th electrode 230a2 overlapping with the second sensing unit SUa-2, and the fourth electrodes 240 may include a fourth electrode 240a2 overlapping with the first sensing unit SUa and the second sensing unit SUa-2.

In an embodiment of the present disclosure, the (2-1)-th electrode 220a may include x first split electrodes 220-dpa spaced apart from each other along the second direction DR2, and the (2-2)-th electrode 220a2 may include y second split electrodes 220-dpa2 spaced apart from each other along the second direction DR2. The (3-1)-th electrode 230a may include x third split electrodes 230-dpa overlapping with the first split electrodes 220-dpa in a one-to-one correspondence, and spaced apart from each other along the second direction DR2. The (3-2)-th electrode 230a2 may include y fourth split electrodes 230-dpa2 overlapping with the second split electrodes 220-dpa2 in a one-to-one correspondence, and spaced apart from each other along the second direction DR2. The x and the y may be integers greater than or equal to 1. In an embodiment of the present disclosure, the x may be greater than or equal to the y, and FIG. 12B illustrates that the x is 3 and the y is 3.

In addition, in an embodiment of the present disclosure, the first electrode 210a2 may include fifth split electrodes 210-dpa2 spaced apart from each other along the first direction DR1, and the fourth electrode 240a2 may include sixth split electrodes 240-dpa2 spaced apart from each other along the first direction DR1.

According to an embodiment of the present disclosure, in order to increase the capacitance of the second sensing unit SUa-2, which is reduced by overlapping with the module region SA, the area of the overlapping region in which one second split electrode 220-dpa2 and one fourth split electrode 230-dpa2 overlap with each other may be designed to be larger than the area of the overlapping region in which one first split electrode 220-dpa and one third split electrode 230-dpa overlap with each other. Therefore, as the second sensing unit SUa-2 overlaps with the module region SA, the reduced signal may be compensated for by the increase in capacitance. Accordingly, the sensing performance of the sensor layer 200 may be improved.

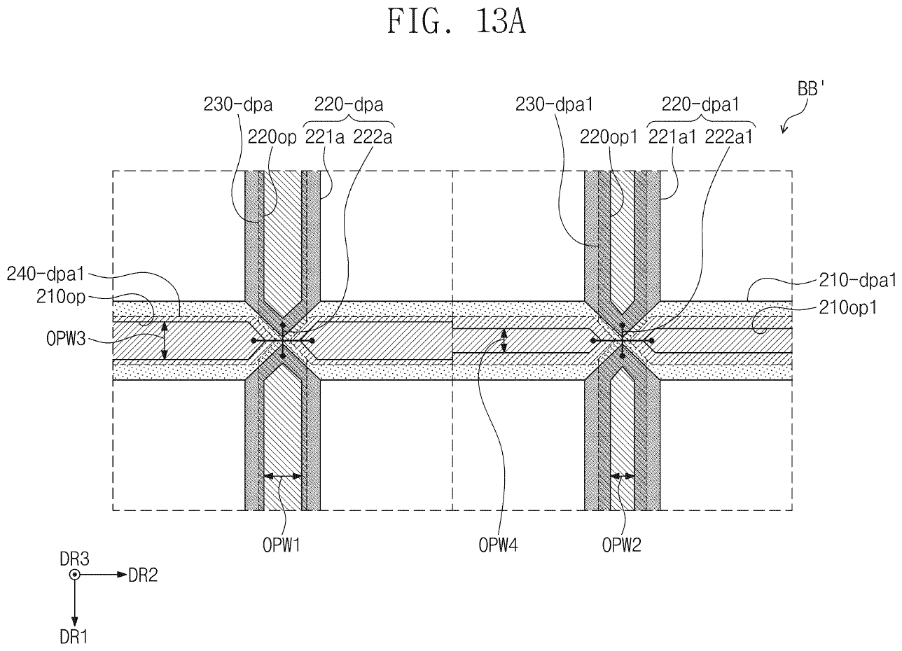

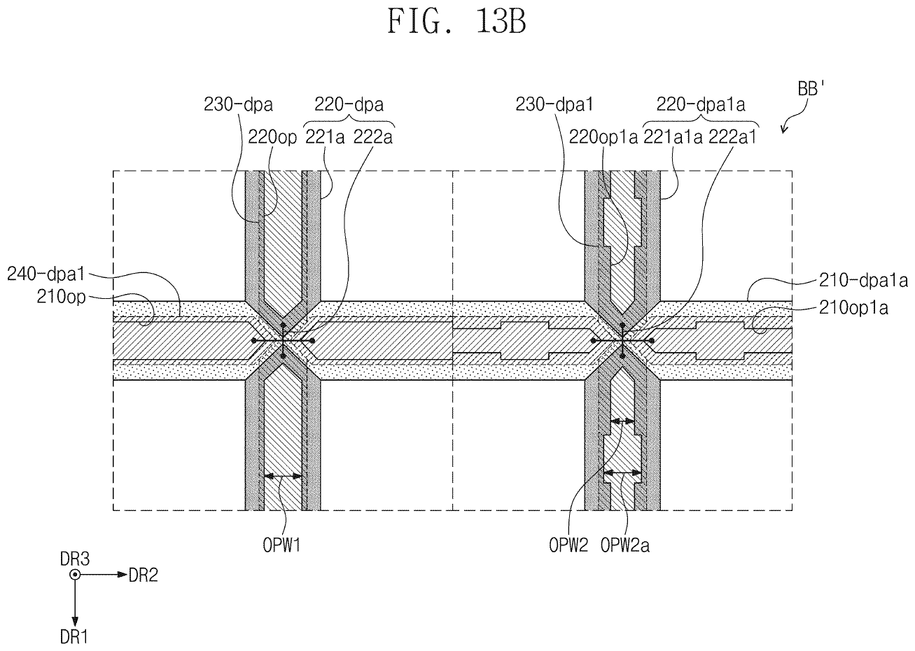

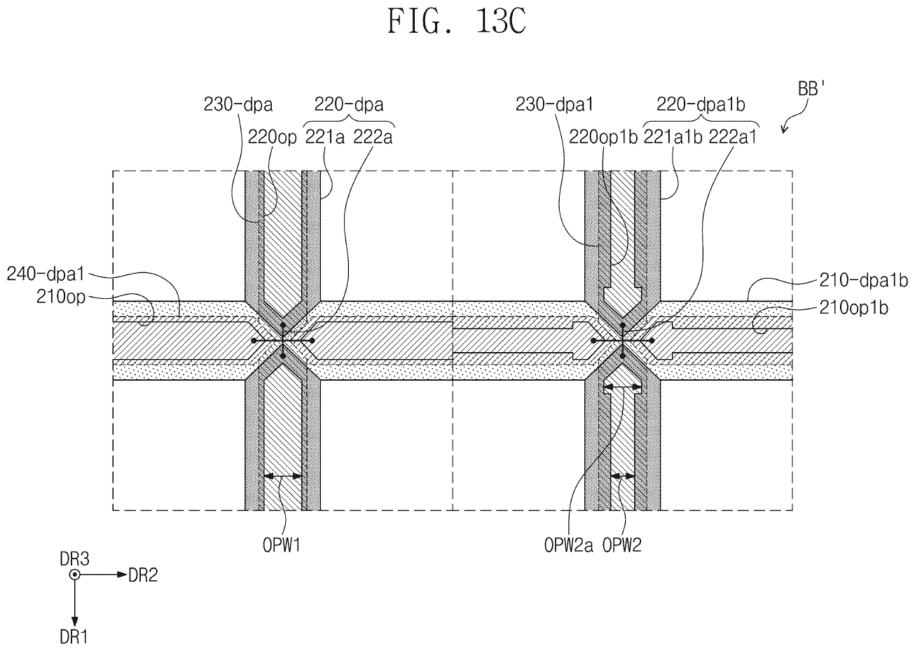

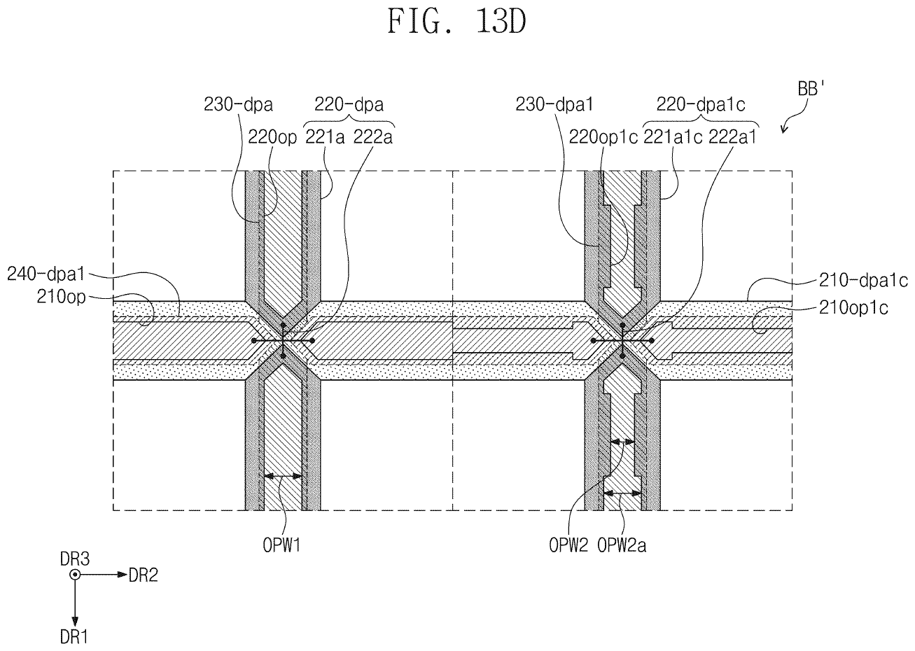

FIG. 13A is an enlarged plan view of the region BB′ illustrated in FIG. 12A.

Referring to FIGS. 12A and 13A, FIG. 13A illustrates the first split electrode 220-dpa of the (2-1)-th electrode 220a and the third split electrode 230-dpa of the (3-1)-th electrode 230a overlapping with the first sensing unit SUa, the second split electrode 220-dpa1 of the (2-2)-th electrode 220a1 and the fourth split electrode 230-dpa1 of the (3-2)-th electrode 230a2 overlapping with the second sensing unit SUa1, and the fifth split electrode 210-dpa1 of the first electrode 210a1 and the sixth split electrode 240-dpa1 of the fourth electrode 240a1 overlapping with the first sensing unit SUa and the second sensing unit SUa1.

In an embodiment of the present disclosure, a first opening 220op may be defined in the (2-1)-th electrode 220a, and a second opening 220op1 having a size smaller than that of the first opening 220op may be defined in the (2-2)-th electrode 220a1.

In an embodiment of the present disclosure, the first split electrode 220-dpa may include a (1-1)-th sensing pattern 221a and a (1-1)-th bridge pattern 222a, and the second split electrode 220-dpa1 may include a (1-2)-th sensing pattern 221a1 and a (1-2)-th bridge pattern 222a1. For example, the first opening 220op may be defined in the (1-1)-th sensing pattern 221a, and the second opening 220op1 may be defined in the (1-2)-th sensing pattern 221a1. In this case, the area of the first split electrode 220-dpa in which the first opening 220op of a relatively larger size is defined may be smaller than the area of the second split electrode 220-dpa1 in which the second opening 220op2 of a relatively smaller size is defined.

In an embodiment of the present disclosure, the third split electrodes 230-dpa and the fourth split electrodes 230-dpa1 may have the same or substantially the same shape as each other. Therefore, the area of each of the third split electrodes 230-dpa and the area of each of the fourth split electrodes 230-dpa1 may be the same or substantially the same as each other.

In an embodiment of the present disclosure, a third opening 210op and a fourth opening 210op1 having a smaller size than that of the third opening 210op may be defined in the fifth split electrode 210-dpa1 of the first electrode 210a1. The third opening 210op may be defined in a region overlapping with the first sensing unit SUa, and the fourth opening 210op1 may be defined in a region overlapping with the second sensing unit SUa1.

In an embodiment of the present disclosure, a first width OPW1 of the first opening 220op in the second direction DR2 is larger than a second width OPW2 of the second opening 220op1 in the second direction DR2. In addition, a third width OPW3 of the third opening 210op in the first direction DR1 is larger than a fourth width OPW4 of the fourth opening 210op1 in the first direction DR1.

FIG. 13B is an enlarged plan view of the region BB′ illustrated in FIG. 12A.

Referring to FIGS. 12A and 13B, FIG. 13B illustrates the first split electrode 220-dpa of the (2-1)-th electrode 220a and the third split electrode 230-dpa of the (3-1)-th electrode 230a overlapping with the first sensing unit SUa, the second split electrode 220-dpa1a of the (2-2)-th electrode 220a1 and the fourth split electrode 230-dpa1 of the (3-2)-th electrode 230a2 overlapping with the second sensing unit SUa1, and the fifth split electrode 210-dpa1a of the first electrode 210a1 and the sixth split electrode 240-dpa1 of the fourth electrode 240a1 overlapping with the first sensing unit SUa and the second sensing unit SUa1.

In an embodiment of the present disclosure, a first opening 220op may be defined in the (2-1)-th electrode 220a, and a second opening 220op1a having a size smaller than that of the first opening 220op may be defined in the (2-2)-th electrode 220a1. The first split electrode 220-dpa may include a (1-1)-th sensing pattern 221a and a (1-1)-th bridge pattern 222a, and the second split electrode 220-dpa1a may include a (1-2)-th sensing pattern 221a1a and a (1-2)-th bridge pattern 222a1. For example, the first opening 220op may be defined in the (1-1)-th sensing pattern 221a, and the second opening 220op1a may be defined in the (1-2)-th sensing pattern 221a1a.

In an embodiment of the present disclosure, a third opening 210op and a fourth opening 210op1a having a smaller size than that of the third opening 210op may be defined in the fifth split electrode 210-dpa1a of the first electrode 210a1. The third opening 210op may be defined in a region overlapping with the first sensing unit SUa, and the fourth opening 210op1a may be defined in a region overlapping with the second sensing unit SUa1.

According to an embodiment of the present disclosure, the first opening 220op may have a first width OPW1 in the second direction DR2, and the second opening 220op1a may include a portion having a second width OPW2 smaller than the first width OPW1, and a portion having a third width OPW2a equal to or substantially equal to the first width OPW1.

In FIG. 13A, the second width OPW2 of the entire second opening 220op1 in the second direction DR2 is designed to be smaller than the first width OPW1, whereas according to the present embodiment as illustrated in FIG. 13B, the second opening 220op1a may have a shape with a partially protruding portion. For example, the third width OPW2a of the portion of the second opening 220op1a having a protruding shape may be designed to be the same or substantially the same as the first width OPW1, and the second width OPW2 of the remaining portion thereof may be designed to be smaller than the first width OPW1.

FIG. 13C is an enlarged plan view of the region BB′ illustrated in FIG. 12A.

Referring to FIGS. 12A and 13C, FIG. 13C illustrates the first split electrode 220-dpa of the (2-1)-th electrode 220a and the third split electrode 230-dpa of the (3-1)-th electrode 230a overlapping with the first sensing unit SUa, the second split electrode 220-dpa1b of the (2-2)-th electrode 220a1 and the fourth split electrode 230-dpa1 of the (3-2)-th electrode 230a2 overlapping with the second sensing unit SUa1, and the fifth split electrode 210-dpa1b of the first electrode 210a1 and the sixth split electrode 240-dpa1 of the fourth electrode 240a1 overlapping with the first sensing unit SUa and the second sensing unit SUa1.

In an embodiment of the present disclosure, a first opening 220op may be defined in the (2-1)-th electrode 220a, and a second opening 220op1b having a size smaller than that of the first opening 220op may be defined in the (2-2)-th electrode 220a1. The first split electrode 220-dpa may include a (1-1)-th sensing pattern 221a and a (1-1)-th bridge pattern 222a, and the second split electrode 220-dpa1a may include a (1-2)-th sensing pattern 221a1b and a (1-2)-th bridge pattern 222a1. For example, the first opening 220op may be defined in the (1-1)-th sensing pattern 221a, and the second opening 220op1b may be defined in the (1-2)-th sensing pattern 221a1b.

In an embodiment of the present disclosure, a third opening 210op and a fourth opening 210op1b having a smaller size than that of the third opening 210op may be defined in the fifth split electrode 210-dpa1b of the first electrode 210a1. The third opening 210op may be defined in a region overlapping with the first sensing unit SUa, and the fourth opening 210op1b may be defined in a region overlapping with the second sensing unit SUa1.

According to an embodiment of the present disclosure, the first opening 220op may have a first width OPW1 in the second direction DR2, and the second opening 220op1b may include a portion having a second width OPW2 smaller than the first width OPW1, and a portion having a third width OPW2a equal to or substantially equal to the first width OPW1.

According to an embodiment of the present disclosure as illustrated in FIG. 13C, the second opening 220op1b may have an arrow shape. For example, the third width OPW2a, which is a maximum width of a portion having the arrow shape of the second opening 220op1b, may be designed to be equal to or substantially equal to the first width OPW1, and the second width OPW2 of the remaining portion thereof may be designed to be smaller than the first width OPW1.

FIG. 13D is an enlarged plan view of the region BB′ illustrated in FIG. 12A.

Referring to FIGS. 12A and 13D, FIG. 13D illustrates the first split electrode 220-dpa of the (2-1)-th electrode 220a and the third split electrode 230-dpa of the (3-1)-th electrode 230a overlapping with the first sensing unit SUa, the second split electrode 220-dpa1c of the (2-2)-th electrode 220a1 and the fourth split electrode 230-dpa1 of the (3-2)-th electrode 230a2 overlapping with the second sensing unit SUa1, and the fifth split electrode 210-dpa1c of the first electrode 210a1 and the sixth split electrode 240-dpa1 of the fourth electrode 240a1 overlapping with the first sensing unit SUa and the second sensing unit SUa1.

In an embodiment of the present disclosure, a first opening 220op may be defined in the (2-1)-th electrode 220a, and a second opening 220op1c having a size smaller than that of the first opening 220op may be defined in the (2-2)-th electrode 220a1. The first split electrode 220-dpa may include a (1-1)-th sensing pattern 221a and a (1-1)-th bridge pattern 222a, and the second split electrode 220-dpa1c may include a (1-2)-th sensing pattern 221a1c and a (1-2)-th bridge pattern 222a1. For example, the first opening 220op may be defined in the (1-1)-th sensing pattern 221a, and the second opening 220op1c may be defined in the (1-2)-th sensing pattern 221a1c.

In an embodiment of the present disclosure, a third opening 210op and a fourth opening 210op1c having a smaller size than that of the third opening 210op may be defined in the fifth split electrode 210-dpa1c of the first electrode 210a1. The third opening 210op may be defined in a region overlapping with the first sensing unit SUa, and the fourth opening 210op1c may be defined in a region overlapping with the second sensing unit SUa1.

According to an embodiment of the present disclosure, the first opening 220op may have a first width OPW1 in the second direction DR2, and the second opening 220op1a may include a portion having a second width OPW2 smaller than the first width OPW1, and a portion having a third width OPW2a equal to or substantially equal to the first width OPW1.

According to an embodiment of the present disclosure as illustrated in FIG. 13D, the second opening 220op1c may have a shape with a partially protruding portion, and the end of the second opening 220op1c may have an arrow shape. For example, the third width OPW2a, which is a maximum width of a portion having the arrow shape of the second opening 220op1c, and the third width OPW2a of a portion having a protruding shape may be designed to be the same or substantially the same as the first width OPW1, and the second width OPW2 of the remaining portion may be designed to be smaller than the first width OPW1.

According to some embodiments of the present disclosure as illustrated in FIGS. 13A to 13D, in order to improve a pen sensing performance, the shapes of portions of the first electrodes 210a1 and the (2-2)-th electrodes 220a1 overlapping with the second sensing unit SUa-1 may be adjusted. Accordingly, in the second sensing unit SUa-1, the capacitance of the capacitor formed between the first electrode 210a1 and the fourth electrode 240a1 and the capacitance of the capacitor formed between the (2-2)-th electrode 220a1 and the (3-2)-th electrode 230a1 may increase. In other words, the reduced signal due to the smaller size of the second sensing unit SUa-1 may be compensated for by the increase in capacitance. Accordingly, the sensing performance of the sensor layer 200 may be improved.

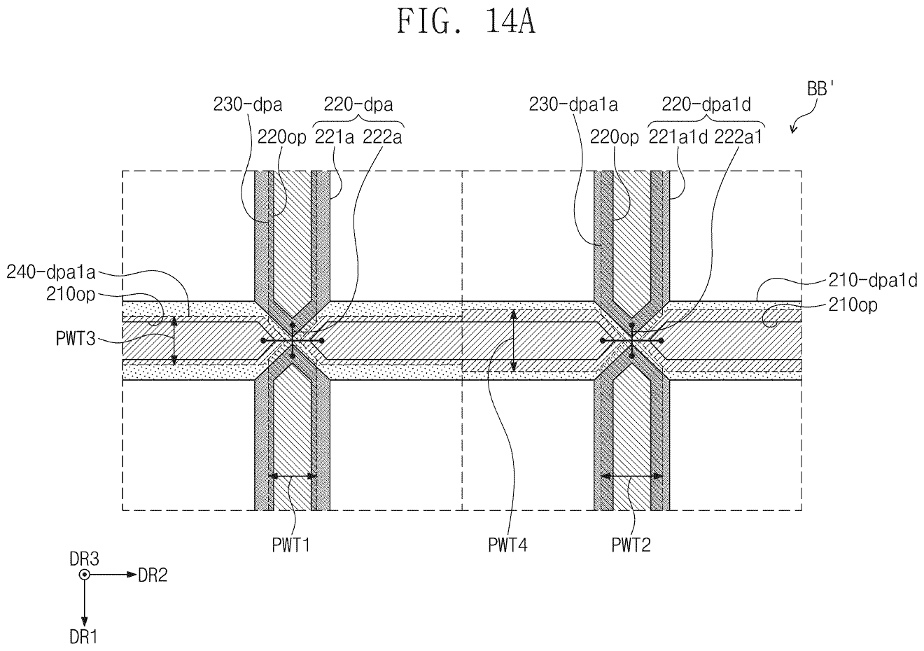

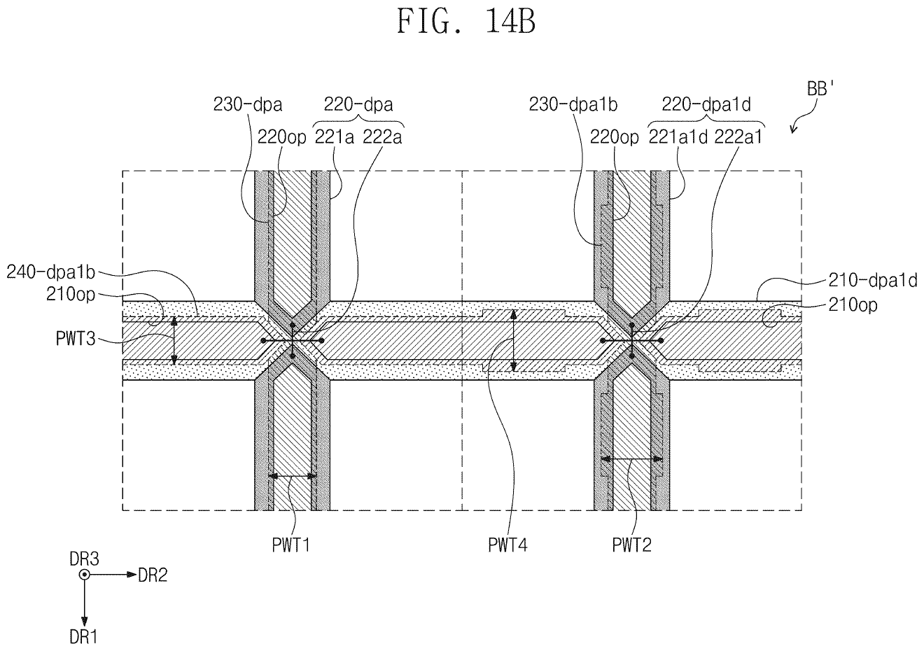

FIG. 14A is an enlarged plan view of the region BB′ illustrated in FIG. 12A.

Referring to FIG. 12A and FIG. 14A, FIG. 14A illustrates the first split electrode 220-dpa of the (2-1)-th electrode 220a and the third split electrode 230-dpa of the (3-1)-th electrode 230a overlapping with the first sensing unit SUa, the second split electrode 220-dpa1d of the (2-2)-th electrode 220a1 and the fourth split electrode 230-dpa1a of the (3-2)-th electrode 230a2 overlapping with the second sensing unit SUa1, and the fifth split electrode 210-dpa1d of the first electrode 210a1 and the sixth split electrode 240-dpa1a of the fourth electrode 240a1 overlapping with the first sensing unit SUa and the second sensing unit SUa1.

In an embodiment of the present disclosure, a first opening 220op may be defined in the (2-1)-th electrode 220a, and a second opening 220op having the same or substantially the same size as that of the first opening 220op may be defined in the (2-2)-th electrode 220a1. The first split electrode 220-dpa may include a (1-1)-th sensing pattern 221a and a (1-1)-th bridge pattern 222a, and the second split electrode 220-dpa1d may include a (1-2)-th sensing pattern 221a1d and a (1-2)-th bridge pattern 222a1. For example, the first opening 220op may be defined in the (1-1)-th sensing pattern 221a, and the second opening 220op may be defined in the (1-2)-th sensing pattern 221a1d.

In an embodiment of the present disclosure, the shape of the (1-1)-th sensing pattern 221a and the shape of the (1-2)-th sensing pattern 221a1d may be the same or substantially the same as each other. The area of each of the first split electrodes 220-dpa and the area of each of the second split electrodes 220-dpa1d may be the same or substantially the same as each other. In addition, third openings 210op may be defined in the fifth split electrode 210-dpa1d of the first electrode 210a1. Some of the third openings 210op may be defined in a region overlapping with the first sensing unit SUa, and others of the third openings 210op may be defined in a region overlapping with the second sensing unit SUa1.

According to an embodiment of the present disclosure, the area of each of the third split electrodes 230-dpa may be smaller than the area of each of the fourth split electrodes 230-dpa1a. For example, a first width PWT1 of the third split electrode 230-dpa in the second direction DR2 may be smaller than a second width PWT2 of the fourth split electrode 230-dpa1a in the second direction DR2. In addition, a third width PWT3 of a portion of the sixth split electrode 240-dpa1a overlapping with the first sensing unit SUa may be smaller than a fourth width PWT4 of a portion thereof overlapping with the second sensing unit SUa1.

FIG. 14B is an enlarged plan view of the region BB′ illustrated in FIG. 12A.

Referring to FIGS. 12A and 14B, FIG. 14B illustrates the first split electrode 220-dpa of the (2-1)-th electrode 220a and the third split electrode 230-dpa of the (3-1)-th electrode 230a overlapping with the first sensing unit SUa, the second split electrode 220-dpa1d of the (2-2)-th electrode 220a1 and the fourth split electrode 230-dpa1b of the (3-2)-th electrode 230a2 overlapping with the second sensing unit SUa1, and the fifth split electrode 210-dpa1d of the first electrode 210a1 and the sixth split electrode 240-dpa1b of the fourth electrode 240a1 overlapping with the first sensing unit SUa and the second sensing unit SUa1.

In FIG. 14A, the second width PWT2 of the entire fourth split electrode 230-dpa1a in the second direction DR2 is designed to be larger than the first width PWT1, whereas according to an embodiment of the present disclosure as illustrated in FIG. 14B, the fourth split electrode 230-dpa1b may have a shape with a partially protruding portion. For example, the second width PWT2 of a portion of the fourth split electrode 230-dpa1b having a protruding shape may be designed to be larger than the first width PWT1, and the remaining portion thereof may be designed to have a shape similar to that of the third split electrode 230-dpa.

According to some embodiments of the present disclosure as illustrated in FIGS. 14A to 14D, in order to improve a pen sensing performance, the shapes of portions of the (3-2)-th electrodes 230a1 and the fourth electrodes 240a1 overlapping with the second sensing unit SUa-1 may be adjusted. Accordingly, in the second sensing unit SUa-1, the capacitance of the capacitor formed between the first electrode 210a1 and the fourth electrode 240a1 and the capacitance of the capacitor formed between the (2-2)-th electrode 220a1 and the (3-2)-th electrode 230a1 may increase. In other words, the detected signal due to the smaller size of the second sensing unit SUa-1 may be compensated for by the increase in capacitance. Accordingly, the sensing performance of the sensor layer 200 may be improved.

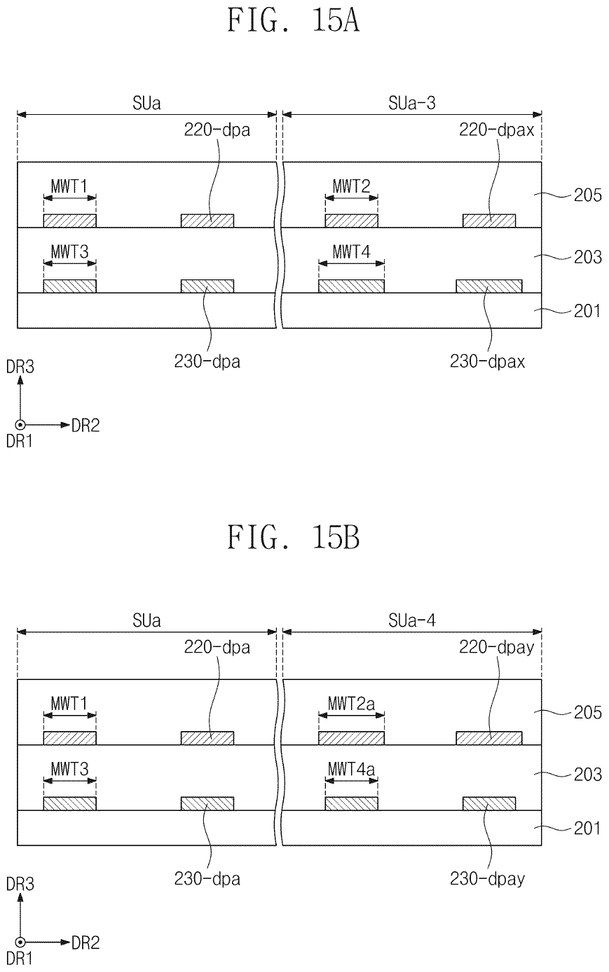

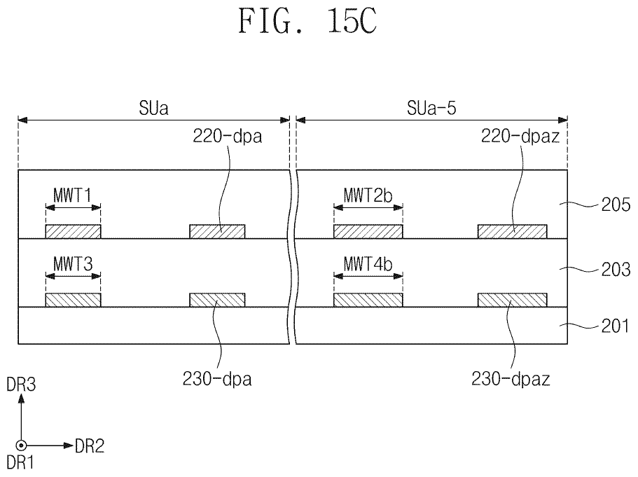

FIG. 15A is a cross-sectional view of a sensor layer according to an embodiment of the present disclosure.

Referring to FIG. 12A and FIG. 15A, the first split electrode 220-dpa of the (2-1)-th electrode 220a disposed in the first sensing unit SUa may have a mesh structure having a first line width MWT1, and the second split electrode 220-dpax of the (2-2)-th electrode 220a1 disposed in the second sensing unit SUa-3 may have a mesh structure having a second line width MWT2. In addition, the third split electrode 230-dpa of the (3-1)-th electrode 230a disposed in the first sensing unit SUa may have a mesh structure having a third line width MWT3, and the fourth split electrode 230-dpax of the (3-2)-th electrode 230a1 disposed in the second sensing unit SUa-3 may have a mesh structure having a fourth line width MWT4.

In an embodiment of the present disclosure, the first line width MWT1 and the second line width MWT2 may be equal to or substantially equal to each other, and the fourth line width MWT4 may be larger than the third line width MWT3. The larger the line width of the mesh structure is, the smaller the size of the opening 200OP (e.g., see FIG. 10) defined in the mesh structure may be.

FIG. 15B is a cross-sectional view of a sensor layer according to an embodiment of the present disclosure.

Referring to FIGS. 12A and 15B, the first split electrode 220-dpa of the (2-1)-th electrode 220a disposed in the first sensing unit SUa may have a mesh structure having a first line width MWT1, and the second split electrode 220-dpay of the (2-2)-th electrode 220a1 disposed in a second sensing unit SUa-4 may have a mesh structure having a second line width MWT2a. In addition, the third split electrode 230-dpa of the (3-1)-th electrode 230a disposed in the first sensing unit SUa may have a mesh structure having a third line width MWT3, and the fourth split electrode 230-dpay of the (3-2)-th electrode 230a1 disposed in the second sensing unit SUa-4 may have a mesh structure having a fourth line width MWT4a.

In an embodiment of the present disclosure, the third line width MWT3 and the fourth line width MWT4a may be equal to or substantially equal to each other, and the second line width MWT2a may be larger than the first line width MWT1.

FIG. 15C is a cross-sectional view of a sensor layer according to an embodiment of the present disclosure.

Referring to FIG. 12A and FIG. 15C, the first split electrode 220-dpa of the (2-1)-th electrode 220a disposed in the first sensing unit SUa may have a mesh structure having a first line width MWT1, and the second split electrode 220-dpaz of the (2-2)-th electrode 220a1 disposed in a second sensing unit SUa-5 may have a mesh structure having a second line width MWT2b. In addition, the third split electrode 230-dpa of the (3-1)-th electrode 230a disposed in the first sensing unit SUa may have a mesh structure having a third line width MWT3, and the fourth split electrode 230-dpaz of the (3-2)-th electrode 230a1 disposed in the second sensing unit SUa-5 may have a mesh structure having a fourth line width MWT4b.

In an embodiment of the present disclosure, the second line width MWT2b may be larger than the first line width MWT1, and the fourth line width MWT4b may be larger than the third line width MWT3.

According to some embodiments as illustrated in FIGS. 15A, 15B, and 15C, it may be possible to expand the line width of the mesh structure of any one of the first to fourth electrodes included in the second sensing unit SUa-3, SUa-4, or SUa-5 having a smaller area than that of the first sensing unit SUa. As the line width expands, the capacitance of the capacitor formed between the first electrode 210a1 and the fourth electrode 240a1 in the second sensing unit SUa-3, SUa-4, or SUa-5 and the capacitance of the capacitor formed between the (2-2)-th electrode 220a1 and the (3-2)-th electrode 230a1 may increase. In other words, the detected signal due to the smaller size of the second sensing unit SUa-3, SUa-4, or SUa-5 may be compensated for by the increase in capacitance. Therefore, the sensing performance of the sensor layer 200 may be improved.

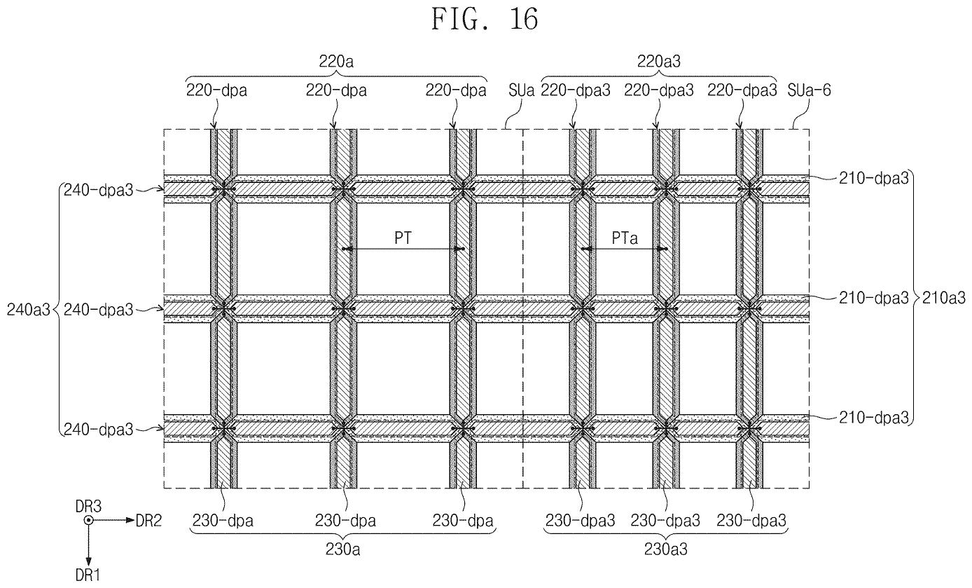

FIG. 16 is a plan view illustrating two sensing units according to an embodiment of the present disclosure.

Referring to FIG. 8 and FIG. 16, the sensing units SU may include a first sensing unit SUa and a second sensing unit SUa-6. The first sensing unit SUa may be spaced apart from the peripheral region 200NA, and the second sensing unit SUa-6 may be in contact with the peripheral region 200NA. In other words, the second sensing unit SUa-6 may be closer to the peripheral region 200NA than the first sensing unit SUa.

The first electrodes 210 may include a first electrode 210a3 overlapping with the first sensing unit SUa and the second sensing unit SUa-6, and the second electrodes 220 may include a (2-1)-th electrode 220a overlapping with the first sensing unit SUa and a (2-2)-th electrode 220a3 overlapping with the second sensing unit SUa-6. The third electrodes 230 may include a (3-1)-th electrode 230a overlapping with the first sensing unit SUa, and a (3-2)-th electrode 230a3 overlapping with the second sensing unit SUa-6. The fourth electrodes 240 may include a fourth electrode 240a3 overlapping with the first sensing unit SUa and the second sensing unit SUa-6.

In an embodiment of the present disclosure, the (2-1)-th electrode 220a may include x first split electrodes 220-dpa spaced apart from each other along the second direction DR2, and the (2-2)-th electrode 220a3 may include y second split electrodes 220-dpa3 spaced apart from each other along the second direction DR2. The (3-1)-th electrode 230a may include x third split electrodes 230-dpa overlapping with the first split electrodes 220-dpa in a one-to-one correspondence, and spaced apart from each other along the second direction DR2. The (3-2)-th electrode 230a3 may include y fourth split electrodes 230-dpa3 overlapping with the second split electrodes 220-dpa3 in a one-to-one correspondence, and spaced apart from each other along the second direction DR2. The x and the y may be integers greater than or equal to 1. In an embodiment of the present disclosure, the x may be greater than or equal to the y, and FIG. 16 illustrates that the x is 3 and the y is 3.

In addition, in an embodiment of the present disclosure, the first electrode 210a2 may include fifth split electrodes 210-dpa2 spaced apart from each other along the first direction DR1, and the fourth electrode 240a2 may include sixth split electrodes 240-dpa2 spaced apart from each other along the first direction DR1.

In an embodiment of the present disclosure, a pitch PT between the first split electrodes 220-dpa may be greater than a pitch PTa between the second split electrodes 220-dpa3. In other words, even though the width of the second sensing unit SUa-1 in the second direction DR2 is reduced, the pitch PTa between the second split electrodes 220-dpa3 may be designed to be smaller than the pitch PT between the first split electrodes 220-dpa, so that the signal may not be reduced even though the size of the second sensing unit SUa-1 is reduced.

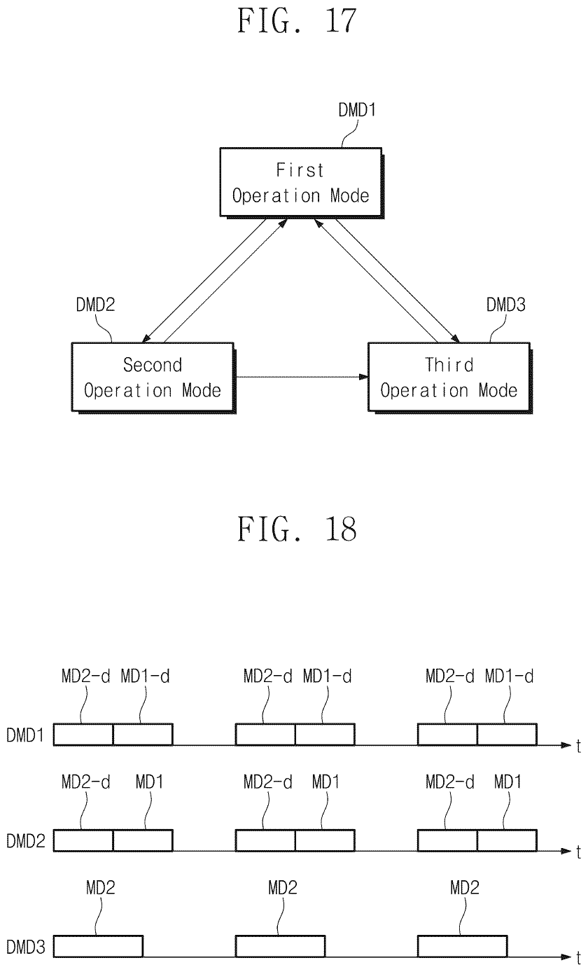

FIG. 17 is a diagram illustrating an operation of the sensor driver 200C (e.g., see FIG. 6) according to an embodiment of the present disclosure.

Referring to FIG. 6 and FIG. 17, the sensor driver 200C may be selectively driven in any one of a first operation mode DMD1, a second operation mode DMD2, and/or a third operation mode DMD3.

The first operation mode DMD1 may be referred to as a touch and pen standby mode. The second operation mode DMD2 may be referred to as a touch activation and pen standby mode. The third operation mode DMD3 may be referred to as a pen activation mode. The first operation mode DMD1 may be a mode that stands by for the first input 2000 and the second input 3000. The second operation mode DMD2 may be a mode that senses the first input 2000, and stands by for the second input 3000. The third operation mode DMD3 may be a mode that senses the second input 3000.

In an embodiment of the present disclosure, the sensor driver 200C may first be driven in the first operation mode DMD1. When the first input 2000 is sensed in the first operation mode DMD1, the sensor driver 200C may be switched (or changed) to the second operation mode DMD2. As another example, when the second input 3000 is sensed in the first operation mode DMD1, the sensor driver 200C may be switched (or changed) to the third operation mode DMD3.

In an embodiment of the present disclosure, when the second input 3000 is sensed in the second operation mode DMD2, the sensor driver 200C may be switched to the third operation mode DMD3. When the first input 2000 is released (e.g., not detected) in the second operation mode DMD2, the sensor driver 200C may be switched to the first operation mode DMD1. When the second input 3000 is released (e.g., not detected) in the third operation mode DMD3, the sensor driver 200C may be switched to the first operation mode DMD1.

FIG. 18 is a diagram illustrating an operation of the sensor driver 200C (e.g., see FIG. 6) according to an embodiment of the present disclosure.

Referring to FIGS. 6, 17, and 18, the operations in the first to third operation modes DMD1, DMD2, and DMD3 are illustrated in chronological order of time t.

In the first operation mode DMD1, the sensor driver 200C may be repeatedly driven in a second mode MD2-d and a first mode MD1-d. During the second mode MD2-d, the sensor layer 200 may be scan-driven to detect the second input 3000. During the first mode MD1-d, the sensor layer 200 may be scan-driven to detect the first input 2000. In FIG. 18, the sensor driver 200C is illustrated as operating in the first mode MD1-d consecutively after the second mode MD2-d, but the order is not limited thereto.

In the second operation mode DMD2, the sensor driver 200C may be repeatedly driven in a second mode MD2-d and a first mode MD1. During the second mode MD2-d, the sensor layer 200 may be scan-driven to detect the second input 3000. During the first mode MD1, the sensor layer 200 may be scan-driven to detect coordinates caused by the first input 2000.

In the third operation mode DMD3, the sensor driver 200C may be driven in a second mode MD2. During the second mode MD2, the sensor layer 200 may be scan-driven to detect coordinates caused by the second input 3000. In the third operation mode DMD3, the sensor driver 200C may not be driven in the first mode MD1-d or MD1 until the second input 3000 is released (e.g., not detected).

Referring to FIG. 8 together, in the first mode MD1-d and the first mode MD1, the third electrodes 230 and the fourth electrodes 240 may both be grounded or applied with a constant voltage. As another example, in the first mode MD1-d and the first mode MD1, the third electrodes 230 and the fourth electrodes 240 may both be floated (e.g., electrically floated). As another example, in the first mode MD1-d and the first mode MD1, a signal in phase with a transmission signal provided to the first electrodes 210 may be applied to the third electrodes 230 and the fourth electrodes 240. In this case, a touch noise may be prevented or substantially prevented from being introduced through the third electrodes 230 and the fourth electrodes 240.

In the second mode MD2-d and the second mode MD2, one ends of the third electrodes 230 and the fourth electrodes 240 may all be floated. In addition, in the second mode MD2-d and the second mode MD2, other ends of the third electrodes 230 and the fourth electrodes 240 may all be grounded or floated. Therefore, compensation of the sensing signal may be maximized or increased by the coupling between the first electrodes 210 and the third electrodes 230 and the coupling between the second electrodes 220 and the fourth electrodes 240.

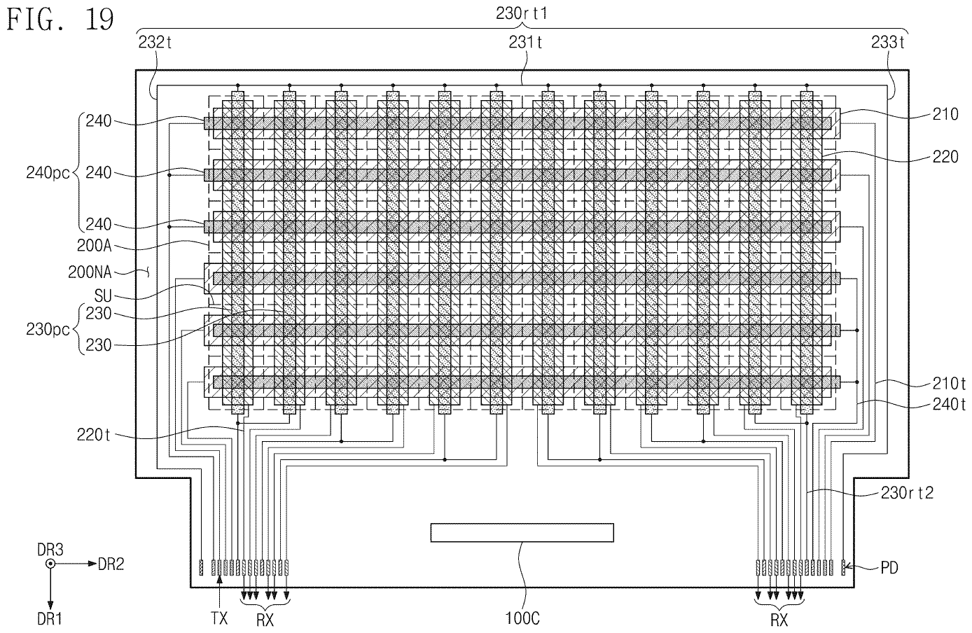

FIG. 19 illustrates a first mode according to an embodiment of the present disclosure.

Referring to FIGS. 6, 18, and 19, the first mode MD1-d of the first operation mode DMD1 and the first mode MD1 of the second operation mode DMD2 may include a mutual capacitance detection mode. FIG. 19 illustrates the mutual capacitance detection mode in the first mode MD1-d of the first operation mode DMD1 and the first mode MD1 of the second operation mode DMD2.

In the mutual capacitance detection mode, the sensor driver 200C may sequentially provide a transmission signal TX to the first electrodes 210, and may detect the coordinates for the first input 2000 using a reception signal RX detected through the second electrodes 220. For example, the sensor driver 200C may sense a change in a mutual capacitance between the first electrodes 210 and the second electrodes 220, and may calculate input coordinates.

FIG. 19 illustrates that the transmission signal TX is provided to one first electrode 210 and the reception signal RX is output from the second electrodes 220. The sensor driver 200C may detect the input coordinates for the first input 2000 by sensing a change in the capacitance between the first electrode 210 and each of the second electrodes 220. In an embodiment of the present disclosure, the transmission signal TX may be sequentially provided to one second electrode 220, and the reception signal RX may be output from the first electrodes 210.

In another embodiment of the present disclosure, at least any one of the first mode MD1-d of the first operation mode DMD1 or the first mode MD1 of the second operation mode DMD2 may further include a self-capacitance detection mode. The sensor driver 200C may output driving signals to the first electrodes 210 and the second electrodes 220 in the self-capacitance detection mode, and may calculate input coordinates by sensing a change in the capacitance of each of the first electrodes 210 and the second electrodes 220.

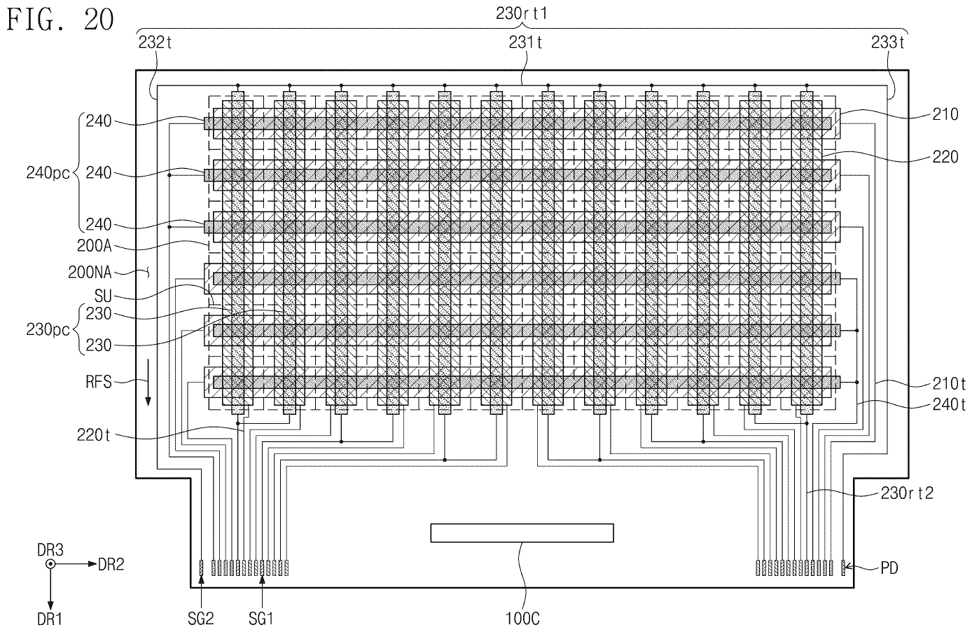

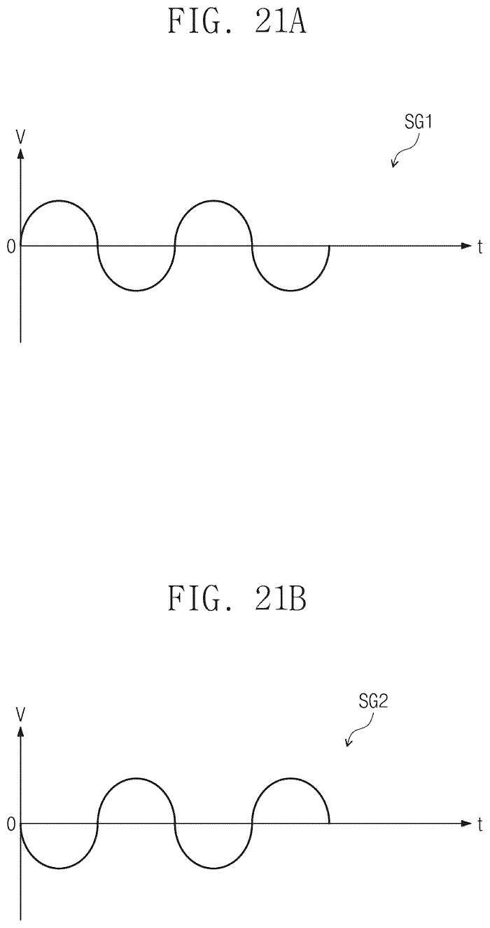

FIG. 20 illustrates a second mode according to an embodiment of the present disclosure. For example, FIG. 20 may illustrate a charging driving mode. FIG. 21A is a graph illustrating a waveform of a first signal according to an embodiment of the present disclosure. FIG. 21B is a graph illustrating a waveform of a second signal according to an embodiment of the present disclosure.

Referring to FIGS. 20, 21A, and 21B, the second mode MD2 may include a charging driving mode. The charging driving mode may include a searching charging driving mode and a tracking charging driving mode.

The searching charging driving mode may be a driving mode prior to sensing the position of a pen. Accordingly, a first signal SG1 or a second signal SG2 may be sequentially provided to all channels included in the sensor layer 200. In other words, the entire region of the sensor layer 200 may be sequentially scanned in the searching charging driving mode. When the pen PN is sensed in the searching charging driving mode, the sensor layer 200 may be driven in the tracking charging driving mode. For example, in the tracking charging driving mode, the sensor driver 200C may sequentially output the first signal SG1 and the second signal SG2 to a region overlapping with a point at which the pen PN is sensed, rather than to the entire sensor layer 200.

In the charging driving mode, the sensor driver 200C may apply the first signal SG1 to one of the third pads PD3 and the fifth pads PD5, and may apply the second signal SG2 to the another pad. The second signal SG2 may be a reverse signal of the first signal SG1. For example, the first signal SG1 may be a sinusoidal signal.

Because the first signal SG1 and the second signal SG2 are applied to at least two pads, a current RFS may have a current path that flows through one pad to another pad. In addition, because the first signal SG1 and the second signal SG2 are sinusoidal signals having a reverse phase relationship with each other, the direction of the current RFS may change periodically. In another embodiment of the present disclosure, the first signal SG1 and the second signal SG2 may be square wave signals having a reverse phase relationship with each other.

When the first signal SG1 and the second signal SG2 have a reverse phase relationship with each other, a noise caused by the first signal SG1 in the display layer 100 (e.g., see FIG. 4) may be offset by a noise caused by the second signal SG2. Therefore, a flicker phenomenon may not occur in the display layer 100, and thus, the display quality of the display layer 100 may be improved.

In another embodiment of the present disclosure, the first signal SG1 may be a sinusoidal signal. However, the present disclosure is not limited thereto, and the first signal SG1 may be a square wave signal, and the second signal SG2 may have a constant voltage (e.g., a predetermined constant voltage). For example, the second signal SG2 may be a ground voltage. In other words, a pad to which the second signal SG2 is applied may be considered to be grounded. Even in this case, the current RFS may flow from one pad to another pad. In addition, even though the other pad is grounded, the direction of the current RFS may periodically change because the first signal SG1 is a sinusoidal signal or a square wave signal.

Referring to FIG. 20, the second signal SG2 is provided to one pad connected to one first loop trace line 230rt1, and the first signal SG1 is provided to one pad connected to the third electrode 230. The current RFS may flow in a current path defined by the second loop trace line 230rt2, the third electrode 230, and a portion of the first loop trace line 230rt1. The current path may have a coil shape. Therefore, in the charging driving mode of the second mode, the resonant circuit of the pen PN may be charged by the current path.

According to some embodiments of the present disclosure, the current path of the loop coil pattern may be implemented by the components included in the sensor layer 200. Therefore, the electronic device 1000 (e.g., see FIG. 2A) may charge the pen PN using the sensor layer 200. Therefore, because a separate component having a coil for charging the pen PN is not required, an increase in the thickness and the weight of the electronic device 1000 and a decrease in the flexibility thereof may not occur.

In the charging driving mode, the first electrodes 210, the second electrodes 220, and the fourth electrodes 240 may be grounded, applied with a constant voltage, or electrically floated. In more detail, the first electrodes 210, the second electrodes 220, and the fourth electrodes 240 may be floated. In this case, the current RFS may not flow to the first electrodes 210, the second electrodes 220, and the fourth electrodes 240.

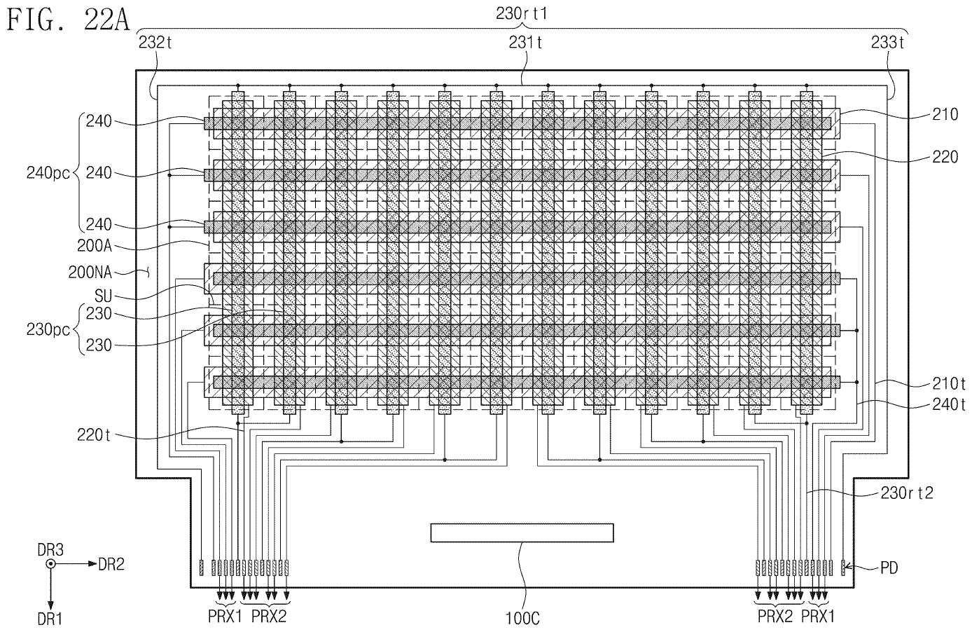

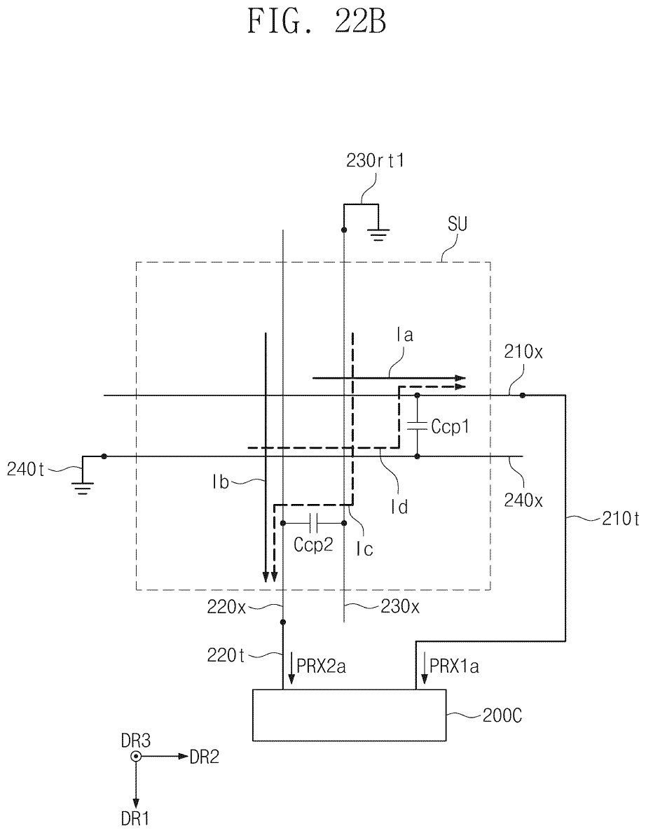

FIG. 22A illustrates a second mode according to an embodiment of the present disclosure. FIG. 22B illustrates the second mode based on one sensing unit according to an embodiment of the present disclosure.

Referring to FIGS. 22A and 22B, the second mode may include a charging driving mode and a pen sensing driving mode. FIGS. 22A and 22B illustrate a pen sensing driving mode.

Referring to FIG. 22A, in the pen sensing driving mode, first reception signals PRX1 may be output from the first electrodes 210, and second reception signals PRX2 may be output from the second electrodes 220. FIG. 22B illustrates one sensing unit SU through which first to fourth induced currents Ia, Ib, Ic, and Id generated by the pen PN flow.

Referring to FIGS. 22A and 22B, in an embodiment of the present disclosure, the routing directions of one electrode and another electrode of the sensor layer 200 overlapping with each other may be different from each other. For example, the routing direction of a first electrode 210x and the routing direction of a fourth electrode 240x may be different from each other. In addition, the routing direction of a second electrode 220x and the routing direction of a third electrode 230x may be different from each other. For example, in FIG. 22B, the first trace line 210t may be connected to the right end of the first electrode 210x, and the auxiliary trace line 240t may be connected to the left end of the fourth electrode 240x. The second trace line 220t may be connected to the lower end of the second electrode 220x, and the first loop trace line 230rt1 may be connected to the upper end of the third electrode 230x.

The RLC resonant circuit of the pen PN may emit a magnetic field at a resonant frequency while discharging a stored charge. By the magnetic field provided by the pen PN, the first induced current Ia may be generated in the first electrode 210x, and the second induced current Ib may be generated in the second electrode 220x. In addition, the third induced current Ic may be generated in the third electrode 230x, and the fourth induced current Id may be generated in the fourth electrode 240x.

A first coupling capacitor Ccp1 may be formed between the fourth electrode 240x and the first electrode 210x, and a second coupling capacitor Ccp2 may be formed between the third electrode 230x and the second electrode 220x. The fourth induced current Id may be transmitted to the first electrode 210x through the first coupling capacitor Ccp1, and the third induced current Ic may be transmitted to the second electrode 220x through the second coupling capacitor Ccp2.

The sensor driver 200C may receive a first reception signal PRX1a based on the first induced current Ia and the fourth induced current Id from the first electrode 210x, and a second reception signal PRX2a based on the second induced current Ib and the third induced current Ic from the second electrode 220x. The sensor driver 200C may detect the input coordinates of the pen PN based on the first reception signal PRX1a and the second reception signal PRX2a.

The sensor driver 200C may receive the first reception signal PRX1a from the first electrode 210x and the second reception signal PRX2a from the second electrode 220x. In this case, the ends of the third electrode 230x and the fourth electrode 240x may both be floated. Therefore, the compensation of the sensing signal may be maximized or increased by the coupling between the first electrode 210x and the fourth electrode 240x and the coupling between the second electrode 220x and the third electrode 230x.

In addition, other ends of the third electrode 230x and the fourth electrode 240x may be grounded or floated. Therefore, the third induced current Ic and the fourth induced current Id may be sufficiently transmitted to the first electrode 210x and the second electrode 220x by the coupling between the first electrode 210x and the fourth electrode 240x and the coupling between the second electrode 220x and the third electrode 230x.

According to some embodiments described above, the plurality of sensing units of the sensor layer may include a first sensing unit, and a second sensing unit having a shape different from that of the first sensing unit. The shapes of portions of the first to fourth electrodes overlapping with the second sensing unit may be adjusted. For example, because the area of the second sensing unit is smaller than that of the first sensing unit, the shapes (or the areas) of portions of the first to fourth electrodes may be designed to be different from the shapes of portions of the first to fourth electrodes overlapping with the first sensing unit, so that the capacitance of the capacitor formed between the first electrode and the fourth electrode and the capacitance of the capacitor formed between the second electrode and the third electrode, which are reduced to that extent, are increased. In this case, the detected signal due to the smaller size of the second sensing unit may be compensated for by the increase in capacitance due to the adjustment of the shapes of portions of the first to fourth electrodes. Therefore, the sensing performance of the sensor layer, or in more detail, the outer portion of the sensing region, may be further improved.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. An electronic device comprising:
a sensor layer having a sensing region, and a peripheral region adjacent to the sensing region; and
a sensor driver configured to drive the sensor layer,
wherein the sensor layer comprises:
a plurality of first electrodes spaced from each other along a first direction;
a plurality of second electrodes spaced from each other along a second direction crossing the first direction;
a plurality of third electrodes overlapping with the plurality of second electrodes; and
a plurality of fourth electrodes overlapping with the plurality of first electrodes,
wherein the sensing region comprises a plurality of sensing units along the first direction and the second direction,
wherein the plurality of sensing units comprise a first sensing unit spaced from the peripheral region, and a second sensing unit in contact with the peripheral region,
wherein the plurality of second electrodes comprise a (2-1)-th electrode overlapping with the first sensing unit, and a (2-2)-th electrode overlapping with the second sensing unit,
wherein the plurality of third electrodes comprise a (3-1)-th electrode overlapping with the (2-1)-th electrode, and a (3-2)-th electrode overlapping with the (2-2)-th electrode, and
wherein a shape of a region overlapping with the (2-1)-th electrode and the (3-1)-th electrode and a shape of a region overlapping with the (2-2)-th electrode and the (3-2)-th electrode are different from each other.

2. The electronic device of claim 1, wherein:
the (2-1)-th electrode comprises x first split electrodes apart from each other along the second direction, where x is an integer; and
the (2-2)-th electrode comprises y second split electrodes spaced from each other along the second direction, where y is an integer.

3. The electronic device of claim 2, wherein the x is larger than the y.

4. The electronic device of claim 2, wherein:
the x and the y are same as each other; and
a pitch between the first split electrodes is larger than a pitch between the second split electrodes.

5. The electronic device of claim 2, wherein:
the (3-1)-th electrode comprises x third split electrodes overlapping with the first split electrodes in a one-to-one correspondence, where x is an integer; and
the (3-2)-th electrode comprises y fourth split electrodes overlapping with the second split electrodes in a one-to-one correspondence, where y is an integer.

6. The electronic device of claim 5, wherein:
an area of each of the first split electrodes and an area of each of the second split electrodes are same as each other; and
an area of each of the third split electrodes is smaller than an area of each of the fourth split electrodes.

7. The electronic device of claim 5, wherein:
an area of each of the first split electrodes is smaller than an area of each of the second split electrodes; and
an area of each of the third split electrodes and an area of each of the fourth split electrodes are same as each other.

8. The electronic device of claim 1, wherein a width of the first sensing unit in the second direction is larger than a width of the second sensing unit in the second direction.

9. The electronic device of claim 1, wherein:
a first opening is in the (2-1)-th electrode; and
a second opening having a size smaller than a size of the first opening is in the (2-2)-th electrode.

10. The electronic device of claim 1, wherein a width of the (3-1)-th electrode in the second direction is smaller than a width of the (3-2)-th electrode in the second direction.

11. The electronic device of claim 1, wherein:
the (2-1)-th electrode has a mesh structure having a first line width;
the (2-2)-th electrode has a mesh structure having a second line width;
the (3-1)-th electrode has a mesh structure having a third line width; and
the (3-2)-th electrode has a mesh structure having a fourth line width.

12. The electronic device of claim 11, wherein:
the first line width and the second line width are same as each other; and
the fourth line width is larger than the third line width.

13. The electronic device of claim 11, wherein:
the third line width and the fourth line width are same as each other; and
the second line width is larger than the first line width.

14. The electronic device of claim 11, wherein:
the second line width is larger than the first line width; and
the fourth line width is larger than the third line width.

15. The electronic device of claim 1, wherein the sensor driver is configured to selectively operate in a first mode for sensing a touch input and in a second mode for sensing a pen input,
wherein the second mode comprises a charging driving mode and a pen sensing driving mode,
wherein in the charging driving mode, the sensor driver is configured to provide a first signal to at least any one third electrode among the plurality of third electrodes, and a second signal to at least another third electrode among the plurality of third electrodes, and
wherein in the pen sensing driving mode, the sensor driver is configured to receive first reception signals from the plurality of first electrodes and second reception signals from the plurality of second electrodes.

16. An electronic device comprising:
a display layer configured to display an image;
a sensor layer on the display layer, and having a sensing region and a peripheral region adjacent to the sensing region; and
a processor configured to control operations of the display layer and the sensor layer,
wherein the sensor layer comprises:
a plurality of first electrodes spaced from each other along a first direction;
a plurality of second electrodes spaced from each other along a second direction crossing the first direction;
a plurality of third electrodes overlapping with the plurality of second electrodes; and
a plurality of fourth electrodes overlapping with the plurality of first electrodes,
wherein the plurality of second electrodes comprise a (2-1)-th electrode, and a (2-2)-th electrode spaced from the (2-1)-th electrode in the second direction,
wherein the plurality of third electrodes comprise a (3-1)-th electrode overlapping with the (2-1)-th electrode, and a (3-2)-th electrode overlapping with the (2-2)-th electrode,
wherein the (3-1)-th electrode comprises a plurality of first split electrodes overlapping with the (2-1)-th electrode,
wherein the (3-2)-th electrode comprises a plurality of second split electrodes overlapping with the (2-2)-th electrode, and
wherein an area of a region, in which each of the plurality of first split electrodes overlaps with the (2-1)-th electrode, is smaller than or equal to an area of a region, in which each of the plurality of second split electrodes overlaps with the (2-2)-th electrode.

17. The electronic device of claim 16, wherein a number of the plurality of first split electrodes is greater than a number of the plurality of second split electrodes.

18. The electronic device of claim 16, wherein:
the (2-1)-th electrode has a mesh structure having a first line width;
the (2-2)-th electrode has a mesh structure having a second line width;
the (3-1)-th electrode has a mesh structure having a third line width; and
the (3-2)-th electrode has a mesh structure having a fourth line width, and wherein:
the first line width and the second line width are same as each other, and the fourth line width is greater than the third line width; or
the third line width and the fourth line width are same as each other, and the second line width is greater than the first line width; or
the second line width is greater than the first line width, and the fourth line width is greater than the third line width.

19. The electronic device of claim 16, wherein:
a first opening is in the (2-1)-th electrode; and
a second opening having a size smaller than a size of the first opening is in the (2-2)-th electrode.

20. The electronic device of claim 16, wherein a width of each of the plurality of first split electrodes in the second direction is smaller than a width of each of the plurality of second split electrodes in the second direction.
